(19) United States
(12) Patent Application Publication
(10) Pub. No.: US 2026/0045401 A1
(43) Pub. Date: Feb. 12, 2026

(54) INTEGRATED INDUCTOR

(71) Applicant: Skyworks Solutions, Inc., Irvine, CA (US)

(72) Inventors: Reza Kasnavi, Solana Beach, CA (US); Behnam Analui, Irvine, CA (US); John Tzung-Yin Lee, Costa Mesa, CA (US)

(21) Appl. No.: 19/291,145

(22) Filed: Aug. 5, 2025

Related U.S. Application Data
(60) Provisional application No. 63/680,522, filed on Aug. 7, 2024.

(51) Int. Cl. H01F 27/28; H01F 1/153; H01F 1/34; H01F 27/24; H03H 9/54

(52) U.S. Cl. CPC H01F 27/2804; H01F 1/15316; H01F 1/342; H01F 27/24; H03H 9/542

(57) ABSTRACT

An integrated inductor is disclosed. The integrated inductor can include a dielectric structure having a first side and a second side opposite the first side, a spiral coil structure between the first side and the second side of the dielectric structure, and a ferromagnetic material structure. The integrated inductor can include a support substrate, and the first side of the dielectric structure can face the support substrate. The ferromagnetic material structure can be positioned at least partially between the support substrate and the second side

### INCORPORATION BY REFERENCE TO ANY PRIORITY APPLICATIONS

Any and all applications for which a foreign or domestic priority claim is identified in the Application Data Sheet as filed with the present application, including U.S. Provisional Patent Application No. 63/680,522, filed on Aug. 7, 2024, titled “INTEGRATED INDUCTOR” are hereby incorporated by reference under 37 CFR 1.57 in their entirety herein.

### BACKGROUND

### Technical Field

The disclosed technology relates to passive devices. Embodiments of this disclosure relate to integrated inductors such as wafer-level integrated inductors or printed circuit board (PCB) level integrated inductors.

### Description of Related Technology

Passive components, such as inductors, can be included in radio frequency (RF) front-end modules. For example, a number of inductors can be included in an RF module for impedance matching between a receive filter and a low-noise amplifier (LNA), and/or as part of a filter circuit. It can be challenging to design an RF module to include a desired number of inductors or to reduce the inductor size to fit in the RF module, especially at low band frequencies. It is challenging to design inductors with ultra-small size with ultra-high performance. In this context, “ultra-small” can refer to minimizing the inductor footprint to meet compact module requirements, while “ultra-high” performance can refer to maintaining high quality factor (Q), inductance stability, and low insertion loss despite the reduced size.

### SUMMARY

The innovations described in the claims each have several aspects, no single one of which is solely responsible for its desirable attributes. Without limiting the scope of the claims, some prominent features of this disclosure will now be briefly described.

In some aspects, the techniques described herein relate to an integrated inductor including: a support substrate; a dielectric structure having a first side facing the support substrate and a second side opposite the first side; a spiral coil structure between the first side and the second side of the dielectric structure; and a ferromagnetic material structure at least partially between the support substrate and the second side.

In some embodiments, the techniques described herein relate to an integrated inductor wherein the ferromagnetic material structure includes a material that has a relative permeability greater than 100.

In some embodiments, the techniques described herein relate to an integrated inductor wherein the relative permeability is in a range between 100 and 1000.

In some embodiments, the techniques described herein relate to an integrated inductor wherein the relative permeability is in a range between 140 and 170.

In some embodiments, the techniques described herein relate to an integrated inductor wherein the relative permeability is in a range between 720 and 780.

In some embodiments, the techniques described herein relate to an integrated inductor wherein the ferromagnetic material structure has a resistivity less than 2000 Ωcm.

In some embodiments, the techniques described herein relate to an integrated inductor wherein the resistivity is in a range between 75 Ωcm and 2000 Ωcm.

In some embodiments, the techniques described herein relate to an integrated inductor wherein the resistivity is in a range between 102 Ωcm and 104 Ωcm.

In some embodiments, the techniques described herein relate to an integrated inductor wherein the resistivity is in a range between 1500 Ωcm and 1700 Ωcm.

In some embodiments, the techniques described herein relate to an integrated inductor wherein the ferromagnetic material structure includes cobalt iron hafnium oxide (CoFeHfO).

In some embodiments, the techniques described herein relate to an integrated inductor wherein the ferromagnetic material structure includes cobalt zirconium tantalum (CoZrTa).

In some embodiments, the techniques described herein relate to an integrated inductor wherein a thickness of the dielectric structure between the first side and the second side is in a range between 45 μm and 150 μm.

In some embodiments, the techniques described herein relate to an integrated inductor wherein the spiral coil structure includes a first coil defined by a first metal layer.

In some embodiments, the techniques described herein relate to an integrated inductor wherein the spiral coil structure further includes a second coil defined by a second metal layer.

In some embodiments, the techniques described herein relate to an integrated inductor is a wafer-level integrated inductor.

In some embodiments, the techniques described herein relate to an integrated inductor wherein the ferromagnetic material structure is patterned to reduce losses due to eddy current.

In some embodiments, the techniques described herein relate to an integrated inductor wherein the ferromagnetic material structure includes slits.

In some embodiments, the techniques described herein relate to an integrated inductor having a core region and a peripheral region, wherein the ferromagnetic material structure includes a core portion positioned in the core region and a peripheral portion positioned in the peripheral region.

In some embodiments, the techniques described herein relate to an integrated inductor wherein at least a portion of the ferromagnetic material structure is positioned laterally between two portions of the spiral coil structure.

In some embodiments, the techniques described herein relate to an integrated inductor wherein at least a portion of the ferromagnetic material structure is positioned between the spiral coil structure and the second side of the dielectric structure.

In some embodiments, the techniques described herein relate to an integrated inductor wherein the ferromagnetic material structure surrounds the spiral coil structure.

In some embodiments, the techniques described herein relate to an integrated inductor wherein at least a portion of the ferromagnetic material structure is positioned over the second side of the dielectric structure.

In some embodiments, the techniques described herein relate to an integrated inductor further includes a ground layer.

In some embodiments, the techniques described herein relate to an inductor die including: the integrated inductor; one or more additional integrated inductors on the support substrate.

In some embodiments, the techniques described herein relate to a packaged acoustic wave device including: a cap structure including the integrated inductor; and an acoustic wave device coupled to the integrated inductor by way of a connecting structure.

In some embodiments, the techniques described herein relate to a packaged acoustic wave device wherein the acoustic wave device includes an acoustic wave filter.

In some embodiments, the techniques described herein relate to a packaged acoustic wave device wherein the acoustic wave filter includes a plurality of acoustic wave resonators arranged to filter a radio frequency signal.

In some aspects, the techniques described herein relate to an integrated inductor having a core region and a peripheral region, the integrated inductor including: a support substrate; a dielectric layer having a first side facing the support substrate and a second side opposite the first side; a spiral coil between the first side and the second side of the dielectric layer; and a ferromagnetic material structure at least in the core region.

In some aspects, the techniques described herein relate to an integrated inductor having a core region and a peripheral region, the integrated inductor including: a support substrate; a dielectric layer having a first side facing the support substrate and a second side opposite the first side; a spiral coil between the first side and the second side of the dielectric layer; and a ferromagnetic material structure at least in the peripheral region.

In some aspects, the techniques described herein relate to an integrated inductor including: a support substrate; a dielectric layer having a first side facing the support substrate and a second side opposite the first side; a spiral coil between the first side and the second side of the dielectric layer; and a ferromagnetic material structure positioned within a magnetic field generated by the spiral coil.

In some aspects, the techniques described herein relate to a method of manufacturing an integrated inductor, the method including: providing a dielectric structure over a support substrate; forming a spiral coil at least partially in the dielectric structure; and forming a ferromagnetic material structure.

In some aspects, the techniques described herein relate to an integrated inductor including: a multi-layer printed circuit board including a stack of layers; a metal layer of the stack of layers at least partially patterned as a spiral coil; and a dielectric layer of the stack of layers having ferromagnetic characteristics at least partially overlapping the spiral coil.

In some aspects, the techniques described herein relate to a method of manufacturing an integrated inductor, the method including: providing a dielectric structure with ferromagnetic characteristics; and forming a spiral coil at least partially in or over the dielectric structure.

### BRIEF DESCRIPTION OF THE DRAWINGS

Embodiments of this disclosure will now be described, by way of non-limiting example, with reference to the accompanying drawings.

FIG. 1A is a schematic cross-sectional side view of an integrated inductor according to an embodiment.

FIG. 1B is a schematic top plan view of the integrated inductor of FIG. 1A.

FIG. 2A is a schematic perspective view of a spiral coil structure of an integrated inductor that includes a first layer and a second layer.

FIG. 2B is a top plan view of the spiral coil structure of FIG. 2A.

FIG. 2C is a schematic side view of the spiral coil structure of FIG. 2A.

FIG. 2D is a schematic cross-sectional side view of the integrated inductor that includes the spiral coil structure of FIG. 2A.

FIG. 3 is a schematic cross-sectional side view of an integrated inductor according to an embodiment.

FIG. 4A is a schematic top plan view of an integrated inductor according to an embodiment.

FIG. 4B is a schematic cross-sectional side view of the integrated inductor of FIG. 4A.

FIGS. 5A to 5D are schematic cross-sectional side views of example stack configuration of integrated inductors in accordance with various embodiments.

FIG. 5E is a top plan view of an integrated inductor according to an embodiment.

FIG. 6A is a schematic top plan view of a single layer spiral coil structure.

FIG. 6B is a schematic top plan view of a double layer spiral coil structure.

FIG. 7A is a chart showing simulation results of five different types of single layer inductors (Type A-E).

FIG. 7B is a chart showing simulation results of five different types of double layer inductors (Type F-I).

FIG. 8A is a graph showing inductance of an integrated inductor of Type B described with respect to FIG. 7A for different engineered material structure dimensions using cobalt iron hafnium oxide (CoFeHfO) as the engineered material structure.

FIG. 8B is a graph showing the quality factor of the integrated inductor of Type B used in FIG. 8A.

FIG. 8C is a graph showing inductance of an integrated inductor of Type B described with respect to FIG. 7A for different engineered material structure dimensions using cobalt zirconium tantalum (CoZrTa) as the engineered material structure.

FIG. 8D is a graph showing the quality factor of the integrated inductor of Type B used in FIG. 8C.

FIG. 9A is a graph showing inductance of an integrated inductor of Type C described with respect to FIG. 7A for different engineered material structure dimensions using CoFeHfO as the engineered material structure.

FIG. 9B is a graph showing the quality factor of the integrated inductor of Type C used in FIG. 9A.

FIG. 9C is a graph showing inductance of an integrated inductor of Type C described with respect to FIG. 7A for different engineered material structure dimensions using CoZrTa as the engineered material structure.

FIG. 9D is a graph showing the quality factor of the integrated inductor of Type C used in FIG. 9C.

FIG. 10A is a graph showing inductance of an integrated inductor of Type D described with respect to FIG. 7A for different engineered material structure dimensions using CoFeHfO as the engineered material structure.

FIG. 10B is a graph showing the quality factor of the integrated inductor of Type D used in FIG. 10A.

FIG. 10C is a graph showing inductance of an integrated inductor of Type D described with respect to FIG. 7A for different engineered material structure dimensions using CoZrTa as the engineered material structure.

FIG. 10D is a graph showing the quality factor of the integrated inductor of Type D used in FIG. 10C.

FIG. 11A is a graph showing inductance of an integrated inductor of Type G described with respect to FIG. 7B for different engineered material structure dimensions using CoFeHfO as the engineered material structure.

FIG. 11B is a graph showing the quality factor of the integrated inductor of Type G used in FIG. 11A.

FIG. 11C is a graph showing inductance of an integrated inductor of Type G described with respect to FIG. 7B for different engineered material structure dimensions using CoZrTa as the engineered material structure.

FIG. 11D is a graph showing the quality factor of the integrated inductor of Type G used in FIG. 11C.

FIG. 12A is a graph showing inductance of an integrated inductor of Type H described with respect to FIG. 7B for different engineered material structure dimensions using CoFeHfO as the engineered material structure.

FIG. 12B is a graph showing the quality factor of the integrated inductor of Type H used in FIG. 12A.

FIG. 12C is a graph showing inductance of an integrated inductor of Type H described with respect to FIG. 7B for different engineered material structure dimensions using CoZrTa as the engineered material structure.

FIG. 12D is a graph showing the quality factor of the integrated inductor of Type H used in FIG. 12C.

FIG. 13A is a graph showing inductance of an integrated inductor of Type I described with respect to FIG. 7B for different engineered material structure dimensions using CoFeHfO as the engineered material structure.

FIG. 13B is a graph showing the quality factor of the integrated inductor of Type I used in FIG. 13A.

FIG. 13C is a graph showing inductance of an integrated inductor of Type I described with respect to FIG. 7B for different engineered material structure dimensions using CoZrTa as the engineered material structure.

FIG. 13D is a graph showing the quality factor of the integrated inductor of Type I used in FIG. 13C.

FIG. 14A is a graph showing the quality factor of an integrated inductor of Type B described with respect to FIG. 7A for different metal thicknesses of the single layer spiral coil structure when CoFeHfO is used as the engineered material structure.

FIG. 14B is a graph showing the quality factor of an integrated inductor of Type B described with respect to FIG. 7A for different metal thicknesses of the single layer spiral coil structure when CoZrTa is used as the engineered material structure.

FIG. 15A is a chart showing the inductance L in nano henry (nH) and the quality factor of integrated inductors of Type A and Type C described with respect to FIG. 7A for different metals of the single layer spiral coil structure when CoFeHfO is used as the engineered material structure.

FIG. 15B is a chart showing the inductance L in nano henry (nH) and the quality factor of integrated inductors of Type A and Type C described with respect to FIG. 7A for different metals of the single layer spiral coil structure when CoZrTa is used as the engineered material structure.

FIG. 16 is a schematic cross-sectional side view of a stack of layers that can be implemented in one or more of the integrated inductors disclosed herein.

FIG. 17A is a chart showing the inductance L in nano henry (nH) and the quality factor of integrated inductors of Type C described with respect to FIG. 7A with the ground layer shown in Figure for different distances between the single layer spiral coil structure and the ground layer when CoFeHfO is used as the engineered material structure.

FIG. 17B is a chart showing the inductance L in nano henry (nH) and the quality factor of integrated inductors of Type C described with respect to FIG. 7A with the ground layer shown for different distances between the single layer spiral coil structure and the ground layer when CoZrTa is used as the engineered material structure.

FIG. 18A is a graph showing inductance as a function of frequency for an inductor having a structure similar to FIG. 5C including TTZ1000 as the material of the engineered material structure.

FIG. 18B is a graph showing quality factor of the inductor of FIG. 18A as a function of frequency for two cases, one when the permeability is constant for TTZ1000 and one where the permeability is a function of frequency as shown in FIGS. 18C and 18E.

FIG. 18C is a graph showing example permeability of TTZ1000 as a function of frequency.

FIG. 18D is a chart showing the inductance and the quality factor of integrated inductors of Type A and Type C when TTZ1000 is used as the material of the engineered material structure.

FIG. 18E is a graph showing permeability of TTZ1000 as a function of frequency.

FIGS. 18F and 18G are charts showing inductance, quality factor, and inductance density simulation results of different inductors.

FIGS. 19A and 19B are graphs showing inductance and the quality factor as a function of thickness of the engineered material structure in an integrated inductor of Type H described with respect to FIG. 7A when CoFeHfO is used as the engineered material structure.

FIGS. 19C and 19D are graphs showing inductance and the quality factor as a function of thickness of the engineered material structure in an integrated inductor of Type H described with respect to FIG. 7A when CoZrTa is used as the engineered material structure.

FIG. 20 is a schematic top plan view of an inductor die according to an embodiment.

FIG. 21 is a schematic cross-sectional side view of a packaged acoustic wave device according to an embodiment.

FIG. 22 is a schematic diagram of a radio frequency module that includes an acoustic wave component.

FIG. 23 is a schematic block diagram of an acoustic wave module according to an embodiment.

FIG. 24 is a schematic diagram of a radio frequency module according to an embodiment.

FIG. 25 is a schematic block diagram of a wireless communication device that includes an integrated inductor according to an embodiment.

### DETAILED DESCRIPTION OF CERTAIN EMBODIMENTS

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings. Any suitable principles and advantages of the embodiments disclosed herein can be implemented together with each other. The headings provided herein are for convenience only and are not intended to affect the meaning or scope of the claims.

A radio frequency (RF) module can include various components such as an antenna, a low-noise amplifier (LNA), a power amplifier (PA), an acoustic wave filter, etc. Acoustic wave filters can filter radio frequency (RF) signals in a variety of applications, such as in an RF front end of a mobile phone. An inductor can be utilized for impedance matching between two or more components in the RF module. For example, the inductor can be configured for impedance matching between the acoustic wave filter (e.g., a receive filter) and the LNA. Surface mount technology (SMT) inductors can be provided in or with the RF module. However, the SMT inductors can be relatively large in size especially for low-band applications that may call for a relatively large inductance (e.g., greater than 20 nH) with a relatively high quality factor Q (e.g., greater than 25). It can be challenging to provide an inductor with desired performance while having a sufficiently compact dimensions to fit in a given area.

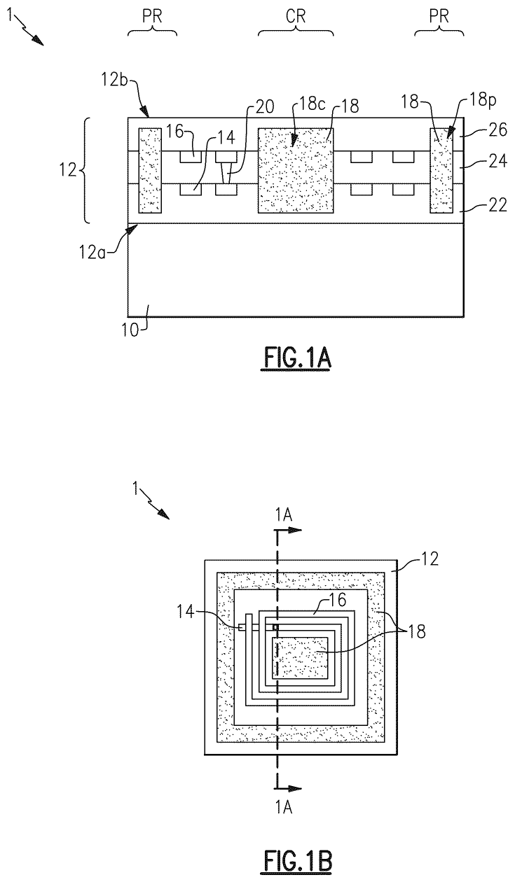

FIG. 1A is a schematic cross-sectional side view of an integrated inductor 1 according to an embodiment. FIG. 1B is a schematic top plan view of the integrated inductor 1 of FIG. 1A. In FIG. 1B, at least some portions of the integrated inductor 1 are made transparent to show internal components. The integrated inductor 1 can be an example of an integrated passive device (IPD) (e.g., a wafer-level integrated inductor) or a printed circuit board (PCB) level integrated inductor. The integrated inductor 1 can include a support substrate 10, a dielectric structure 12, a first metal layer 14, a second metal layer 16, and an engineered material structure 18. The integrated inductor 1 can also include a via 20 that connects the first and second metal layers 14, 16.

The support substrate 10 can be a semiconductor substrate. The support substrate 10 can be a silicon substrate. The support substrate 10 can be any other suitable support substrate, such as a substrate including quartz, silicon carbide, sapphire, glass, gallium arsenide, or any suitable ceramic (e.g., spinel, alumina, etc.). The support substrate 10 can have a relatively high resistivity.

The dielectric structure 12 can include a plurality of dielectric layers, in some embodiments. For example, the dielectric structure can include a first layer 22, a second layer 24, and a third layer 26. The dielectric structure 12 can include any suitable material(s). The dielectric structure 12 can include silicon dioxide (SiO₂), silicon nitride (Si₃N₄), aluminum oxide (Al₂O₃), hafnium oxide (HfO₂), or tantalum oxide (Ta₂O₅). The dielectric structure 12 may include a hexagonal dielectric ferrite, such as TTZ1000 manufactured by Skyworks, Inc. TTZ100 can have a relative permeability μᵣ in a range between 5 and 10. In some embodiments, the dielectric structure 12 can be provided by way of deposition, such as chemical vapor deposition (CVD) or physical vapor deposition (PVD). The first to third layers 22, 24, 26 can include the same material or different materials. In some embodiments, the dielectric structure 12 can include a material that has a relative permittivity Er of about 2.8. For example, the relative permittivity of the material of the dielectric structure 12 can be in a range between 1.5 and 3.5, or 2 and 3.

The dielectric structure 12 can have a first side 12a facing the support substrate 10 and a second side 12b opposite the first side 12a. The first side 12a can be part of the first layer 22 and the second side 12b can be part of the third layer 26.

The first and second metal layers 14, 16 can include any suitable metal(s). For example, the first metal layer 14 and/or the second metal layer 16 can include copper, aluminum, silver, or gold. In some embodiments, the first metal layer 14 and/or the second metal layer 16 can be provided by way of deposition, such as chemical vapor deposition (CVD) or physical vapor deposition (PVD).

The first metal layer 14 can include a metal trace that is arranged as a spiral coil. Similarly, the second metal layer 16 can include a metal trace that is arranged as a spiral coil. In FIGS. 1A and 1B, the first and second metal layers 14, 16 have two rounds or turns. However, a skilled artisan will understand that the spiral coils can have any suitable turn counts. The first metal layer 14 and the second metal layer 16 can overlap as shown in FIGS. 1A and 1B. However, in some other embodiments, the first metal layer 14 and the second metal layer 16 can be offset from one another. An integrated inductor disclosed herein can include any suitable number of metal layer(s). For example, there may be three, four, or more metal layers each of which forming a spiral coil in a single integrated inductor 1. The first metal layer 14 and the second metal layer 16 are shown as having a single layer structure. However, each metal layer may include a multi-layer structure having two or more layers therein.

The engineered material structure 18 can include any suitable ferromagnetic material. The engineered material structure 18 can include a material that has a relatively high permeability. In some embodiments, the engineered material structure 18 can have a relative permeability μᵣ greater than 100. For example, the engineered material structure 18 can have a relative permeability μᵣ in a range between 100 and 1000, 140 and 170, or 720 and 780. In some embodiments, the engineered material structure 18 can have a resistivity less than 2000 Ωcm. For example, the engineered material structure 18 can have a resistivity in a range between 75 Ωcm and 2000 Ωcm, 102 Ωcm and 104 Ωcm, or 1500 Ωcm and 1700 Ωcm. In some embodiments, the engineered material structure 18 can include cobalt iron hafnium oxide (CoFeHfO), cobalt zirconium tantalum (CoZrTa), or a ferrite having a relatively high permeability.

The engineered material structure 18 can be positioned between the second side 12b of the dielectric structure 12 and the support substrate 10. The engineered material structure 18 can include a core portion 18c positioned in a core region CR of the integrated inductor 1 and a peripheral portion 18p in a peripheral region PR of the integrated inductor 1. The first and second metal layers 14, 16 can be positioned between the core region CR and the peripheral region PR. Although the engineered material structure 18 is provided only in the core region CR and the peripheral region PR in FIGS. 1A and 1B as an example, the engineered material structure 18 can be provided at any suitable location(s) of the integrated inductor 1 as shown in other embodiments disclosed herein.

The engineered material structure 18 (e.g., a ferromagnetic material) can contribute to confining magnetic field in a relatively small volume, and, as a result, a larger inductance density may be achieved within a given volume as compared to a similar inductor without the engineered material structure 18. The integrated inductor 1 with the engineered material structure 18 can have the first metal layer 14 and/or the second metal layer 16 with a shorter length or a smaller size for the given volume as compared to the similar inductor without the engineered material structure 18, while providing a desired inductance. The shorter length or smaller size can provide lower losses and hence the integrated inductor 1 with the engineered material structure 18 can improve the Q performance.

The dielectric structure 12 has a thickness from the first side 12a to the second side 12b. The thickness of the dielectric structure 12 can be selected based on various factors such as, a desired inductance, a number of spiral coils, and a distance between adjacent spiral coils. In some embodiments, the thickness of the dielectric structure 12 can be in a range between 45 μm and 150 μm, 65 μm and 100 μm, or 75 μm and 85 μm. For example, the thickness of the dielectric structure 12 can be about 78 μm.

The dimensions of the first and second metal layers 14, 16 can be selected based at least in part on desired performance, such as desired inductance, a maximum loss, and/or the desired quality factor Q. In some embodiments, the first metal layer 14 can have a thickness in a range between 5 μm and 20 μm, 7 μm and 17 μm, or 10 μm and 15 μm. Similarly, the second metal layer 16 can have a thickness in a range between 5 μm and 20 μm, 7 μm and 17 μm, or 10 μm and 15 μm. For example, the thicknesses of the first and second metal layers 14, 16 can be about 12 μm. A lateral dimension of the first and second metal layers 14, 16 in a plan view including the core region CR can be in a range between, for example, 200 μm×200 μm and 800 μm×800 μm, or 400 μm×400 μm and 700 μm×700 μm. In some embodiments, the lateral dimension of the first and second metal layers 14, 16 can be about 627 μm×537 μm. The first and second metal layers 14, 16 much smaller or much larger dimensions in some other embodiments. A gap between the first metal layer 14 and the second metal layer 16 can be in a range between 5 μm and 30 μm, 10 μm and 25 μm, or 15 μm and 20 μm. For example, the gap can be about 18 μm.

The integrated inductor 1 can be manufactured in any suitable manner. In some embodiments, the integrated inductor 1 can be manufactured by way of a wafer-level processing, a complementary metal-oxide-semiconductor (CMOS) processing, a silicon on insulator (SOI) processing, a gallium arsenide heterojunction bipolar transistor (GaAs HBT) processing, or a silicon germanium (SiGe) processing. The integrated inductor 1 manufactured by way of the wafer-level processing can be referred to as a wafer-level integrated inductor. The integrated inductor 1 manufactured by way of the complementary metal-oxide-semiconductor (CMOS) processing can be referred to as a CMOS inductor. The integrated inductor 1 manufactured by way of the silicon on insulator (SOI) processing can be referred to as an SOI inductor. The integrated inductor 1 manufactured by way of the gallium arsenide heterojunction bipolar transistor (GaAs HBT) processing can be referred to as a GaAs HBT inductor. The integrated inductor 1 manufactured by way of the silicon germanium (SiGe) processing can be referred to as a SiGe inductor.

A method of manufacturing the integrated inductor 1 according to an embodiment can include providing the support substrate 10. The method can include providing the first layer 22 of the dielectric structure 12 over the support substrate 10. Providing the first layer 22 can include depositing a dielectric material by way of, for example, chemical vapor deposition (CVD) or physical vapor deposition (PVD).

The method can include forming the first metal layer 14. Forming the first metal layer 14 can include, for example, removing (e.g., etching) at least a portion of the first layer 22 to form a trench and providing the first metal layer 14 in the trench in the first layer 22. The trench in the first layer 22 may be patterned to define the shape of the first metal layer 14. In some other embodiments, the first metal layer 14 can be formed on a surface of the first layer 22 without the removing process.

The method can include providing the second layer 24 of the dielectric structure 12 over the first layer 22 and the first metal layer 14. Providing the second layer 24 can include depositing a dielectric material by way of, for example, chemical vapor deposition (CVD) or physical vapor deposition (PVD).

The method can include forming the via 20 and the second metal layer 16. Forming the via 20 can include, for example, removing (e.g., etching) at least a portion of the second layer 24 to form a through via and providing (e.g., depositing) a conductive material in the through via. The via 20 can be a filled via or a conformal via. Forming the second metal layer 16 can include, for example, removing (e.g., etching) at least a portion of the second layer 24 to form a trench and providing the second metal layer 16 in the trench in the second layer 24. The trench in the second layer 24 may be patterned to define the shape of the second metal layer 16. The through via and the trench in the second layer 24 may be formed in a single process. In some other embodiments, the second metal layer 16 can be formed on a surface of the second layer 24 without the removing process. The via 20 can make contact with the first metal layer 14 and the second metal layer 16.

The method can include providing the third layer 26 of the dielectric structure 12 over the second layer 24 and the second metal layer 16. Providing the third layer 26 can include depositing a dielectric material by way of, for example, chemical vapor deposition (CVD) or physical vapor deposition (PVD).

The method can also include forming the engineered material structure 18. Forming the engineered material structure 18 can include removing (e.g., etching) at least a portion of the dielectric structure 12 to form one or more cavities and providing the engineered material in the one or more cavities. In some embodiments, portions of the first and second layers 22, 24 of the dielectric structure 12 can be removed to form one or more cavities and the engineered material can be provided in the one or more cavities. The engineered material may overflow from the one or more cavities and disposed over a surface of the second layer 22. The overflown portion of the engineered material can be patterned to remove excess engineered material. The third layer 26 can be provided over the second layer 22 and the engineered material structure 18. There may be any suitable number of dielectric layers in the dielectric structure 12 to enable formation of any suitable shape of the engineered material structure 18 at any location(s) of the integrated inductor 1.

In some embodiments, the integrated inductor 1 may be manufactured by way of PCB or similar processing. For example, the PCB may include a stack of multiple interchanging layers of (i) metal, e.g. copper, silver, or gold, and (ii) laminate, ceramic, or ferromagnetic dielectric. There may be vias that can connect various metal layers to each other. The metal in each layer may be designed to have any geometric shape (e.g., a spiral). A multi-layer spiral may be formed by connecting spirals in different layers. The spiral may be formed such that the interlayer dielectrics above or below the metal layer(s) are magnetics. One or multiple inductors may be manufactured in the same process and may be next to each other. One or multiple inductors may be manufactured in the same PCB in or on which rest of circuits or components for an RF front-end resides. In other words, the PCB inductor(s) may be built as a stand-alone integrated passive device that can be mounted with other components in a module, or the PCB inductor(s) can be built in or be embedded in the PCB that is housing the rest of module interconnects. An example stack of metal and dielectric layers can include some or all of the dielectric layers that are also ferromagnetic. The metal may be patterned in each layer and layers may be connected through vias. In some embodiments, the spiral can be surrounded by the ferromagnetic dielectric. For example, the ferromagnetic dielectric can be provided over, below, and/or between the windings that form the spirals.

In some embodiments, the method of manufacturing the integrated inductor 1 can also include singulating (e.g., dicing) the integrated inductor 1 from a larger wafer level structure. In some embodiments, there can be two or more inductors after singulation. For example, an integrated inductor die can include two or more inductors having the structure of integrated inductor 1. In some embodiments, a singulated inductor can have a structural indication of the singulating process such as a surface roughness that indicates a dicing process.

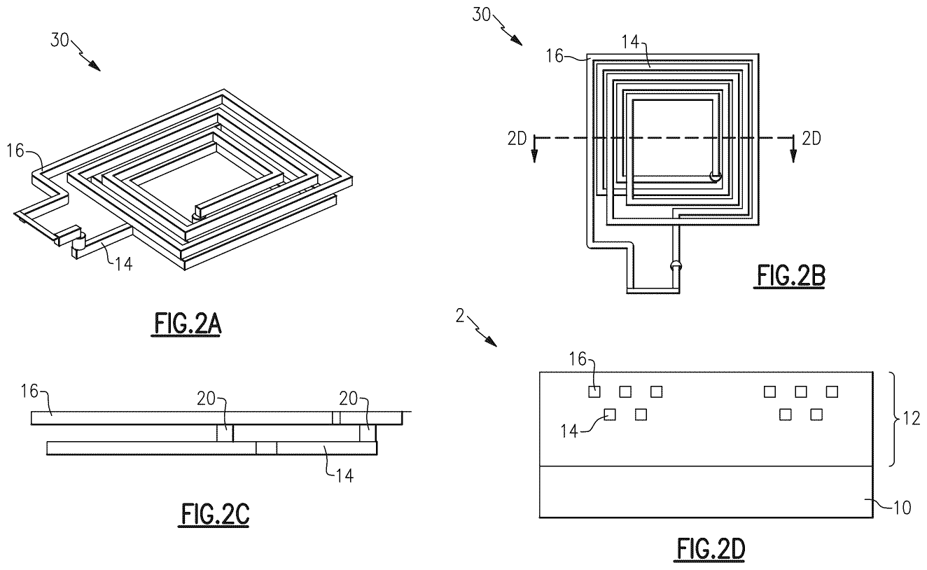

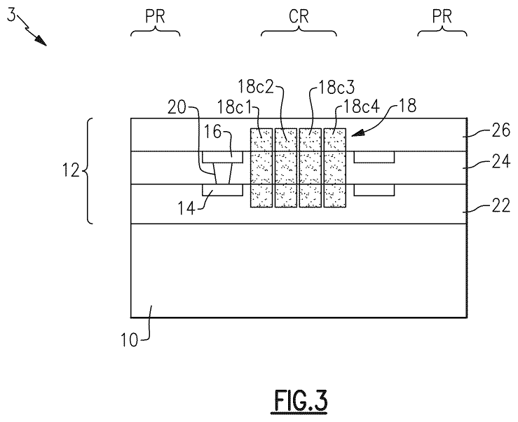

FIG. 2A is a schematic perspective view of a spiral coil structure 30 of an integrated inductor 2 that includes a first layer 14 and a second layer 16. FIG. 2B is a top plan view of the spiral coil structure 30 of FIG. 2A. FIG. 2C is a schematic side view of the spiral coil structure 30 of FIG. 2A. FIG. 2D is a schematic cross-sectional side view of the integrated inductor 2 that includes the spiral coil structure 30 of FIG. 2A. Unless otherwise noted, the components shown in FIGS. 2A to 2D may be structurally and/or functionally the same as or generally similar to like components disclosed herein. As shown in FIGS. 2A-2D, the first metal layer 14 and the second metal layer 16 may be laterally offset from one another, in some embodiments. In some embodiments, the first metal layer 14 and the second metal layer 16 can partially overlap.

FIG. 3 is a schematic cross-sectional side view of an integrated inductor 3 according to an embodiment. Unless otherwise noted, the components of the integrated inductor 3 shown in FIG. 3 may be structurally and/or functionally the same as or generally similar to like components of integrated inductors disclosed herein. FIG. 3 illustrates that an engineered material structure 18 can be patterned. Patterning the engineered material structure 18 can contribute to reducing losses from, for example, eddy current, in certain applications. As shown in FIG. 3, the engineered material structure 18 in the core region CR can include slices of engineered material including a first core portion 18cl, a second core portion 18c2, a third core portion 18c3, and a fourth core portion 18c4. The engineered material structure 18 is shown to have four core portions in FIG. 3. However, the engineered material structure 18 may be patterned in any other suitable manner.

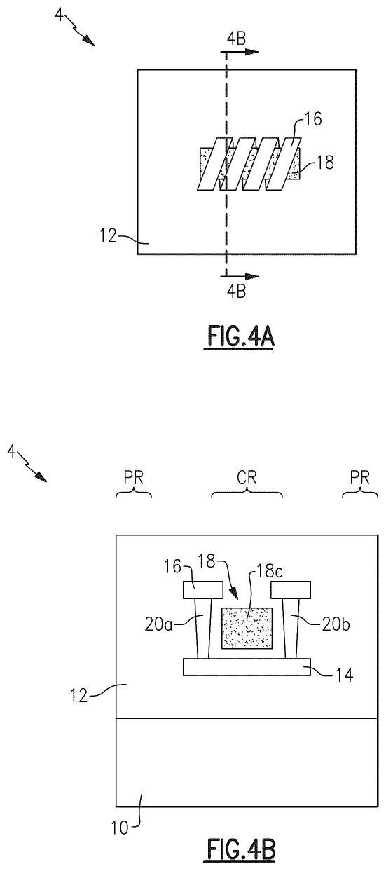

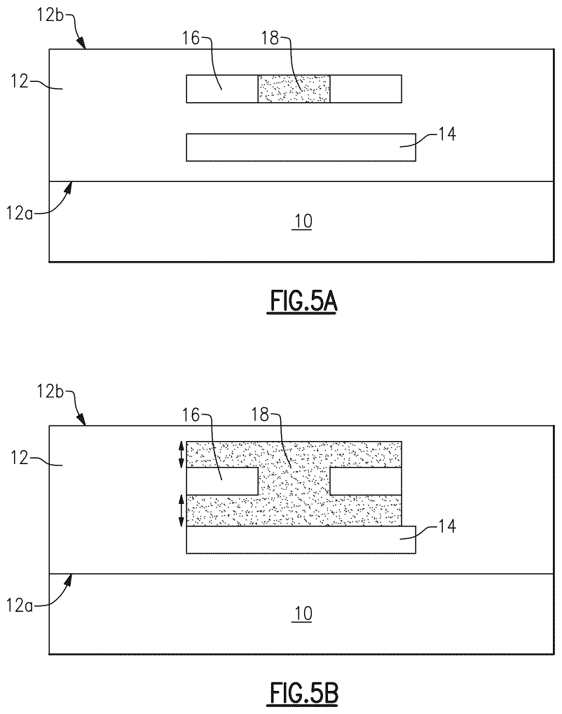

FIG. 4A is a schematic top plan view of an integrated inductor 4 according to an embodiment. FIG. 4B is a schematic cross-sectional side view of the integrated inductor 4 of FIG. 4A. In FIG. 4A, at least some portions of the integrated inductor 1 are made transparent to show internal components. Unless otherwise noted, the components of the integrated inductor 4 shown in FIGS. 4A and 4B may be structurally and/or functionally the same as or generally similar to like components of integrated inductors disclosed herein.

FIGS. 1A to 3 show the spiral coils formed laterally around the core region CR. However, an integrated inductor can be arranged in any other suitable orientations. The integrated inductor 4 shown in FIGS. 4A and 4B illustrates that the winding can be formed non-parallel (e.g., generally perpendicular) to a surface of the support substrate 10 that faces the dielectric structure 12. The integrated inductor 4 can include a first metal layer 14 that extends through the center region CR at a first height from the support substrate 10, a second metal layer 16 that extends through the center region CR at a second height from the support substrate 10, a first via 20a that connects portions of the first and second metal layers 14, 16, and a second via 20b that connects different portions of the first and second metal layers 14, 16. There can be additional vias that connects other portions of the first and second metal layers 14, 16. The first layer 14, the second layer 16, and the vias including the first and second vias 20a, 20b can define a coil structure wound around a core portion 18c of an engineered material structure 18. A skilled artisan will understand that the engineered material structure 18 of the integrated inductor 4 can include other suitable portions outside of the core region CR (see, for example, FIGS. 1A and 1B) or the core portion 18c can have multiple portions of engineered material (see, for example, FIG. 3).

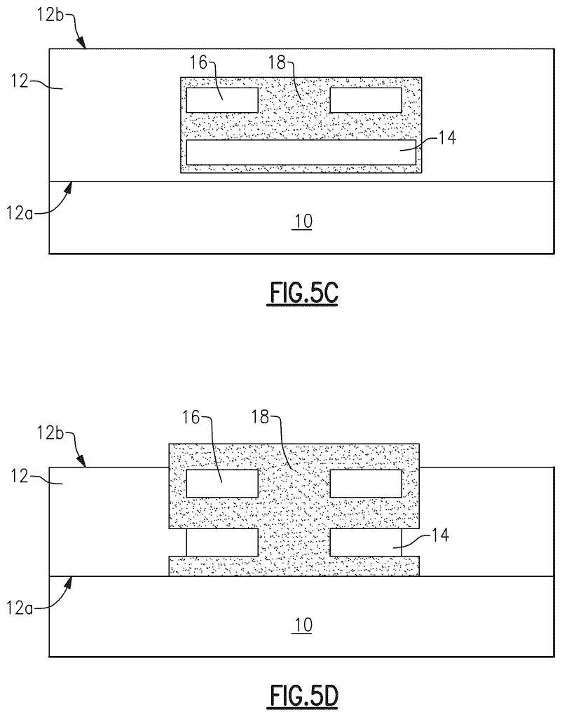

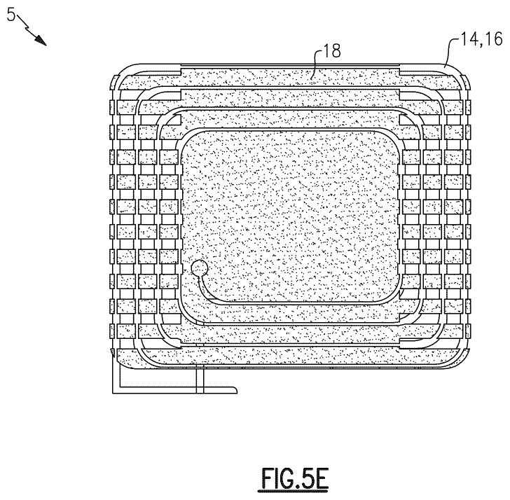

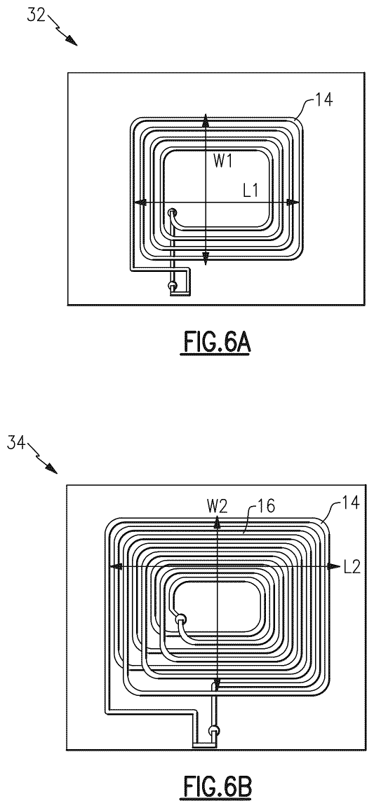

Locations and/or dimensions of an engineered material structure 18 in an integrated inductor can be significant in providing a relatively compact, low loss, high Q integrated inductor with relatively high inductance. FIGS. 5A-5D illustrate examples of different locations where the engineered material structure 18 can be located relative to metal layers (e.g., the first and second metal layers 14, 16) that define spiral coils.

FIGS. 5A to 5D are schematic cross-sectional side views of various stacks of layers that can be implemented in one or more of the integrated inductors disclosed herein. Unless otherwise noted, the components shown in FIGS. 5A to 5D may be structurally and/or functionally the same as or generally similar to like components disclosed herein. Although the first layer 14 shown in FIGS. 5A to 5C are illustrated as extending laterally in the cross-sections, these figures are shown to represent a general stack-up, and the first layer 14 can have a spiral shape in some embodiments.

FIG. 5A shows that the engineered material structure 18 can be provided at least partially between two portions of the second metal layer 16. The gap between the two portions of the second metal layer 16 can represent a core region CR of an integrated inductor, in some applications.

FIG. 5B shows that, in addition to a portion the engineered material structure 18 provided at least partially between two portions of the second metal layer 16 illustrated in FIG. 5A, the engineered material structure 18 can be provided at least partially between the first and second metal layers 14, 16 and/or at least partially between the second metal layer 16 and the second side 12b of the dielectric structure 12. In some embodiments, the portion of the engineered material structure 18 positioned between the first and second metal layers 14, 16 may be isolated from the first metal layer 14 by a portion of the dielectric structure 12.

FIG. 5C shows that, in some embodiments, the first and second metal layers 14, 16 can be surrounded by the engineered material structure 18. For example, the first and second metal layers 14, 16 can be embedded in the engineered material structure 18. The engineered material structure 18 can be provided at least partially between portions of the second metal layer 16, at least partially between the first and second metal layers 14, 16, at least partially between the second metal layer 16 and the second side 12b of the dielectric structure 12, and/or at least partially between the support substate 10 and the first metal layer 14.

FIG. 5D shows that the engineered material structure 18 can be provided at least partially between portions of the second metal layer 16, at least partially between portions of the first metal layer 14, at least partially between the first and second metal layers 14, 16, over the second side 12b of the dielectric structure 12, and/or at least partially between the support substate 10 and the first metal layer 14. In some embodiments, the engineered material structure 18 can make contact with the support substrate 10.

In some embodiments, the engineered material structure 18 can be patterned as shown in FIG. 5E. FIG. 5E is a top plan view of an integrated inductor 5 according to an embodiment. A dielectric structure (the dielectric structure 12 shown in one or more other figures) is omitted in FIG. 5E to show internal components. Unless otherwise noted, the components shown in FIG. 5E may be structurally and/or functionally the same as or generally similar to like components disclosed herein.

The integrated inductor 5 can include a spiral coil defined by a first metal layer 14 and/or a second metal layer 16, and an engineered material structure 18. The engineered material structure 18 can be patterned to include slits under portions of the spiral coil. Patterning the engineered material structure 18 as shown in FIG. 5E can contribute to reducing losses and improving the quality factor Q.

The principles and advantages of the engineered material structure 18 can be implemented in any suitable stack configuration(s). For example, the engineered material structure 18 can be implemented in, for example, a PCB structure in a similar manner as shown in FIGS. 5A-5E without the support substrate 10.

Simulations can be conducted to determine dimensions and locations of the engineered material structure 18 for providing a desired inductor performance. Simulation results of simulations conducted for various embodiments of the stack configurations of FIGS. 5A and 5B will be described below. In these simulations, two different types of spiral coils are used.

FIG. 6A is a schematic top plan view of a single layer spiral coil structure 32. The single layer spiral coil structure 32 has a width W1 and a length L1. FIG. 6B is a schematic top plan view of a double layer spiral coil structure 34. The double layer spiral coil structure 34 can be generally similar to the spiral coil structure 30 shown in FIGS. 2A and 2B. The double layer spiral coil structure 34 has a width W2 and a length L2.

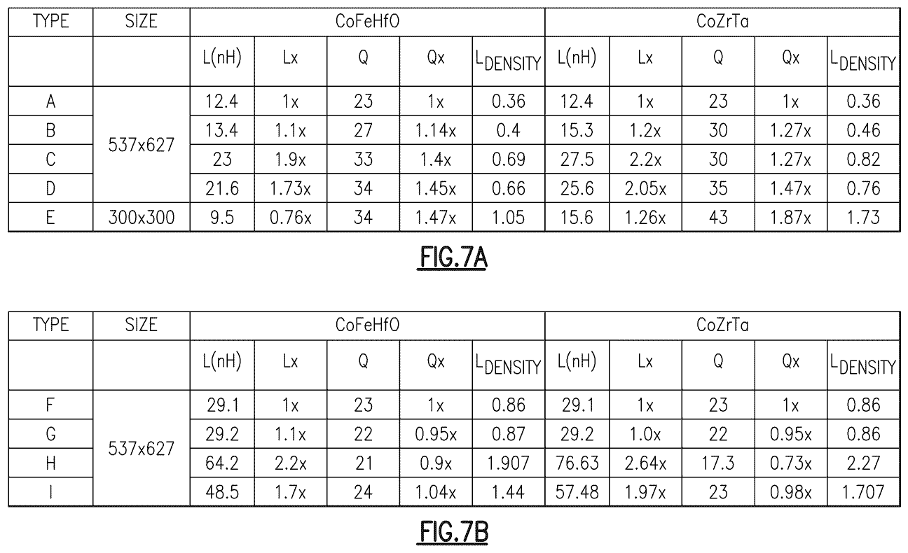

FIG. 7A is a chart showing simulation results of five different types of single layer inductors (Type A-E). Types A-E each includes the single layer spiral coil structure 32 shown in FIG. 6A, and the simulations are conducted over a range of frequencies and Q is measured at frequency of 0.63 GHz. Each of Types A-E includes a silicon substrate as the support substrate 10, a 12 μm thick metal trace forming the single layer spiral coil structure 32, and a dielectric material having relative permittivity Er of about 2.8 as the dielectric structure 12. Type A does not include any engineered material structure. Type B includes the engineered material structure 18 in the core region CR laterally between portions of the single layer spiral coil structure 32 as shown in FIG. 5A with the second layer 16 and the engineered material structure 18. Type C and Type E include the engineered material structure 18 above, below, and laterally between portions of the single layer spiral coil structure 32 as shown in FIG. 5B with the second layer 16 and the engineered material structure 18. Type D is similar to Type C but the engineered material structure 18 in Type D is patterned as shown in FIG. 5E. Types A-D have a lateral dimension of 537 μm×627 μm, and Type E has a lateral dimension of 300 μm×300 μm. For each of Types B-E, simulations are conducted with cobalt iron hafnium oxide (CoFeHfO) as the engineered material structure 18 and cobalt zirconium tantalum (CoZrTa) as the engineered material structure 18.

The simulation results of FIG. 7A indicate that, for the same lateral dimensions, Types B-E can provide higher inductance values than Type A. Also, the quality factor improved in Types B-E as compared to Type A. The simulation results of FIG. 7A indicate that including the engineered material structure 18 in an integrated inductor as disclosed herein can enable size reduction and/or performance improvement.

FIG. 7B is a chart showing simulation results of five different types of double layer inductors (Type F-I). Types F-I are generally similar to Types A-D except that the single layer spiral coil structure 32 used in Types A-D are replaced with the double layer spiral coil structure 34 shown in FIG. 6B.

The simulation results of FIG. 7B indicate that for the same lateral dimension, Types G-I can provide higher inductance values. Also, the quality factor in Types G-I are comparable to Type A. The simulation results of FIG. 7B indicate that including the engineered material structure 18 in an integrated inductor can enable size reduction. The simulation results of FIG. 7B indicate similar tendency as the simulation results of FIG. 7A.

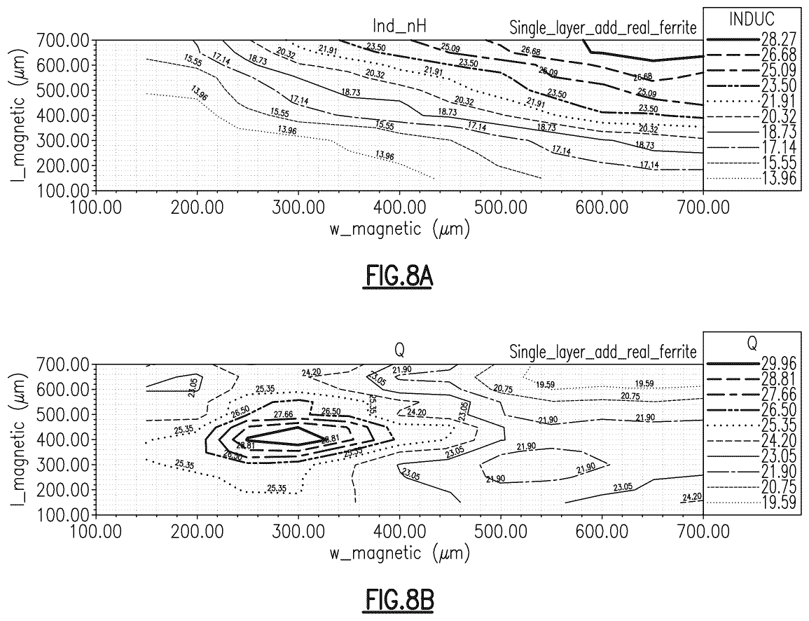

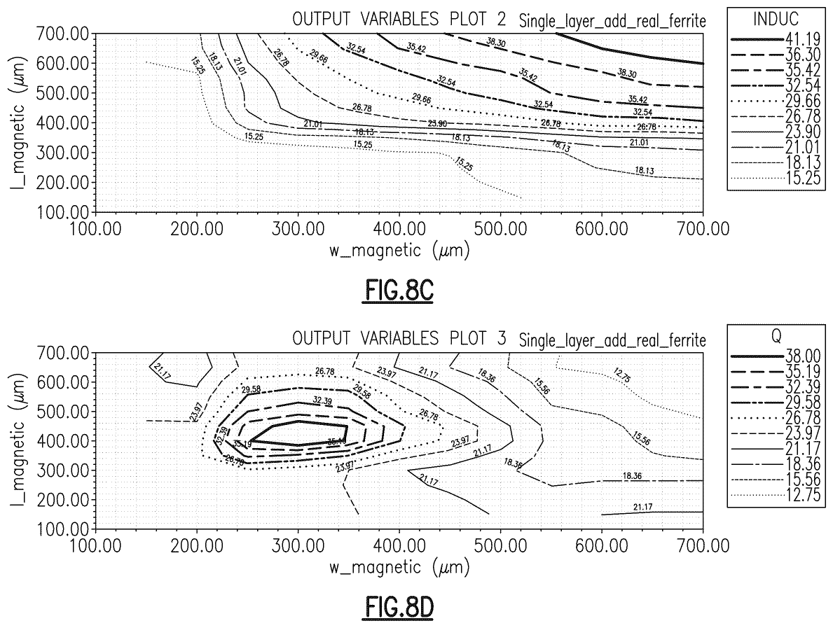

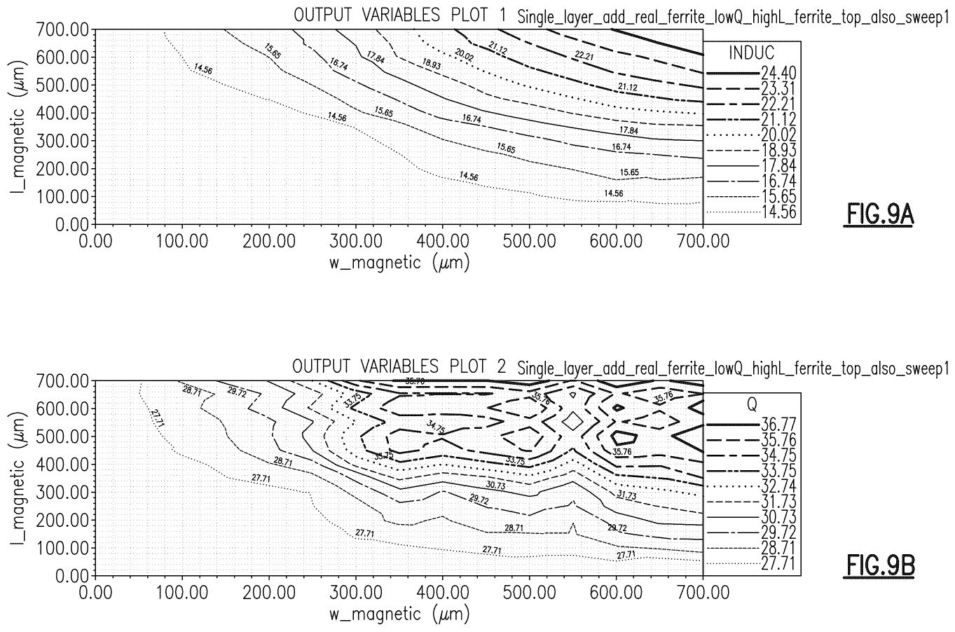

The engineered material structure dimensions can be selected based at least in part on the inductance and the quality factor. FIGS. 8A-13D show various simulation results showing the inductance and the quality factor for different inductors.

FIG. 8A is a graph showing inductance of an integrated inductor of Type B described with respect to FIG. 7A for different engineered material structure dimensions using cobalt iron hafnium oxide (CoFeHfO) as the engineered material structure 18. FIG. 8B is a graph showing the quality factor of the integrated inductor of Type B used in FIG. 8A. FIG. 8C is a graph showing inductance of an integrated inductor of Type B described with respect to FIG. 7A for different engineered material structure dimensions using cobalt zirconium tantalum (CoZrTa) as the engineered material structure 18. FIG. 8D is a graph showing the quality factor of the integrated inductor of Type B used in FIG. 8C.

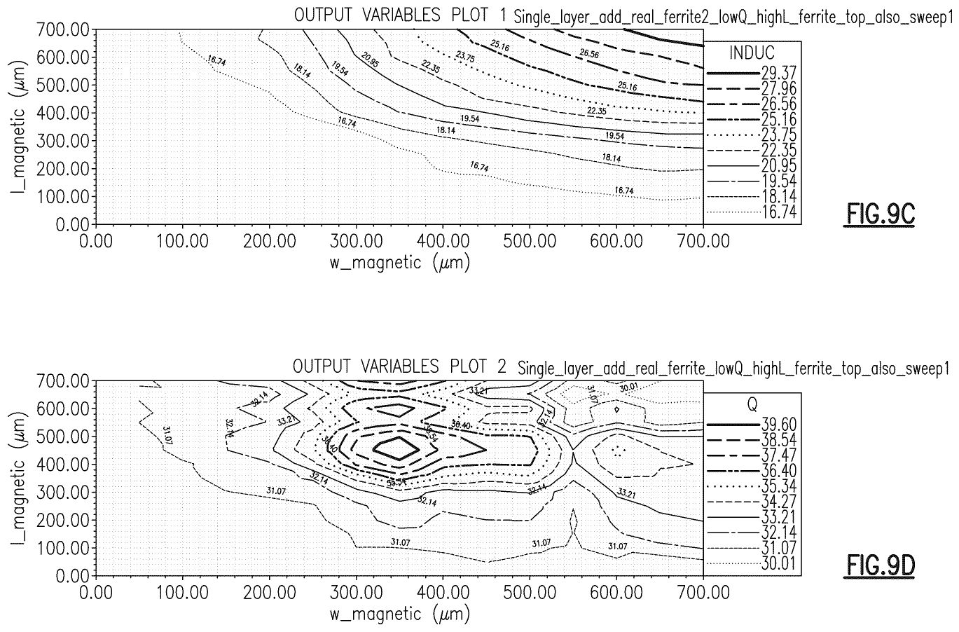

FIG. 9A is a graph showing inductance of an integrated inductor of Type C described with respect to FIG. 7A for different engineered material structure dimensions using cobalt iron hafnium oxide (CoFeHfO) as the engineered material structure 18. FIG. 9B is a graph showing the quality factor of the integrated inductor of Type C used in FIG. 9A. FIG. 9C is a graph showing inductance of an integrated inductor of Type C described with respect to FIG. 7A for different engineered material structure dimensions using cobalt zirconium tantalum (CoZrTa) as the engineered material structure 18. FIG. 9D is a graph showing the quality factor of the integrated inductor of Type C used in FIG. 9C.

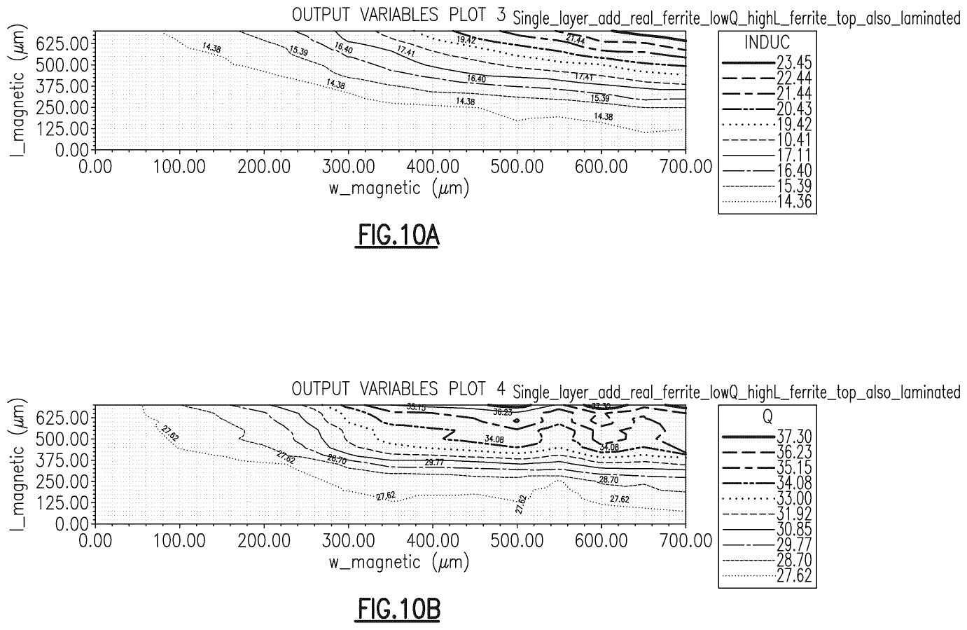

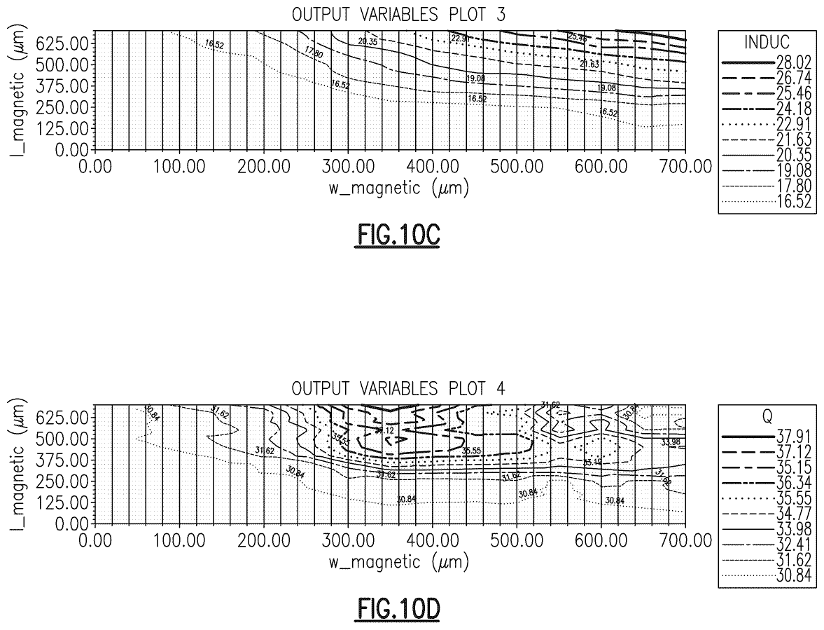

FIG. 10A is a graph showing inductance of an integrated inductor of Type D described with respect to FIG. 7A for different engineered material structure dimensions using cobalt iron hafnium oxide (CoFeHfO) as the engineered material structure 18. FIG. 10B is a graph showing the quality factor of the integrated inductor of Type D used in FIG. 10A. FIG. 10C is a graph showing inductance of an integrated inductor of Type D described with respect to FIG. 7A for different engineered material structure dimensions using cobalt zirconium tantalum (CoZrTa) as the engineered material structure 18. FIG. 10D is a graph showing the quality factor of the integrated inductor of Type D used in FIG. 10C.

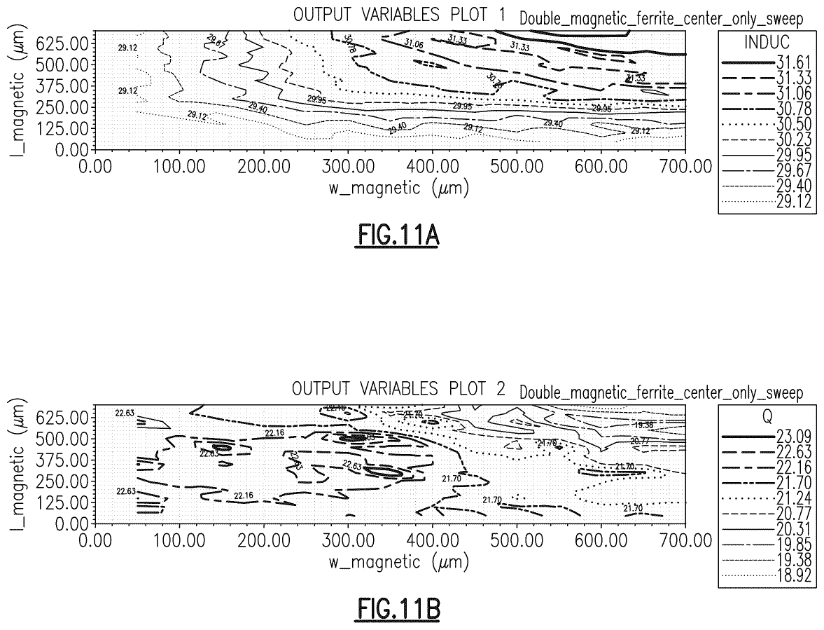

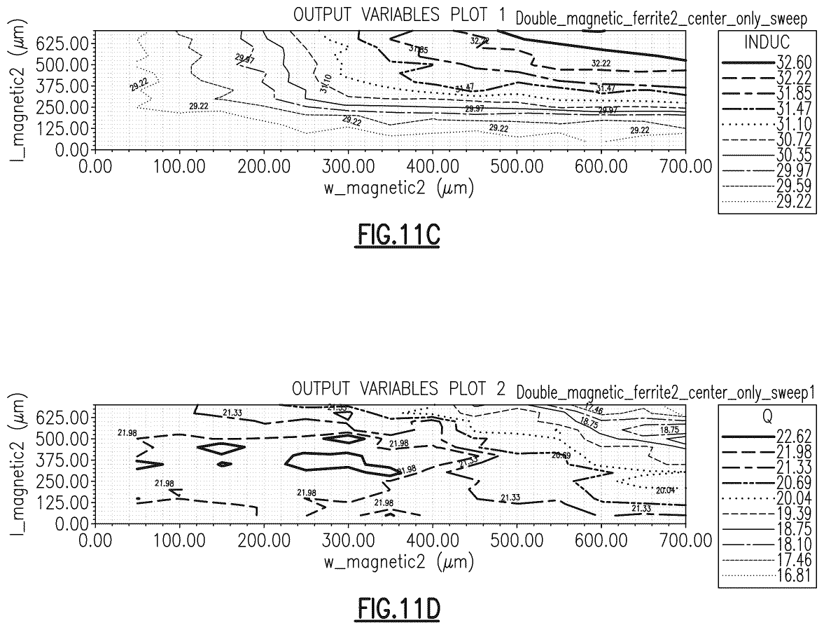

FIG. 11A is a graph showing inductance of an integrated inductor of Type G described with respect to FIG. 7B for different engineered material structure dimensions using cobalt iron hafnium oxide (CoFeHfO) as the engineered material structure 18. FIG. 11B is a graph showing the quality factor of the integrated inductor of Type G used in FIG. 11A. FIG. 11C is a graph showing inductance of an integrated inductor of Type G described with respect to FIG. 7B for different engineered material structure dimensions using cobalt zirconium tantalum (CoZrTa) as the engineered material structure 18. FIG. 11D is a graph showing the quality factor of the integrated inductor of Type G used in FIG. 11C.

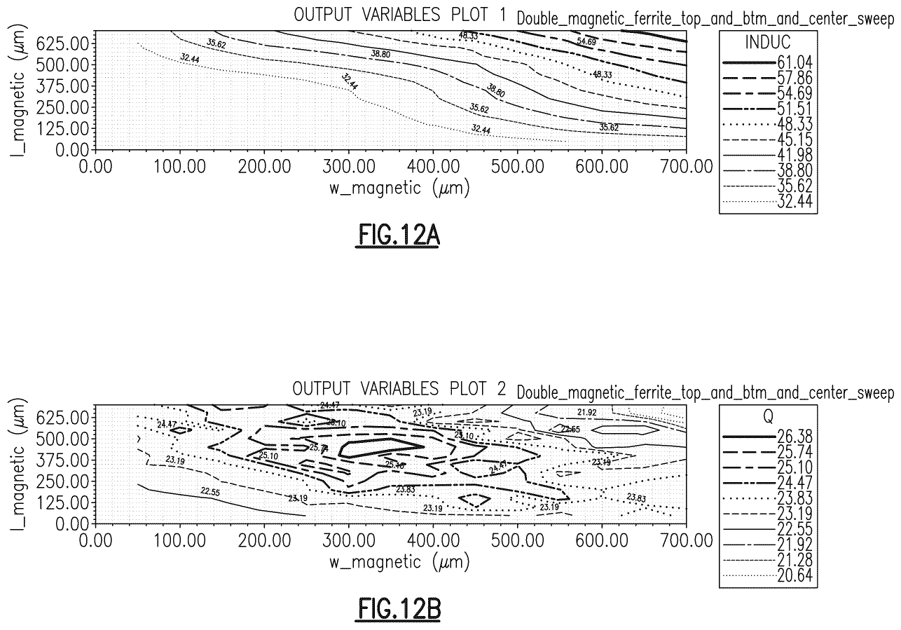

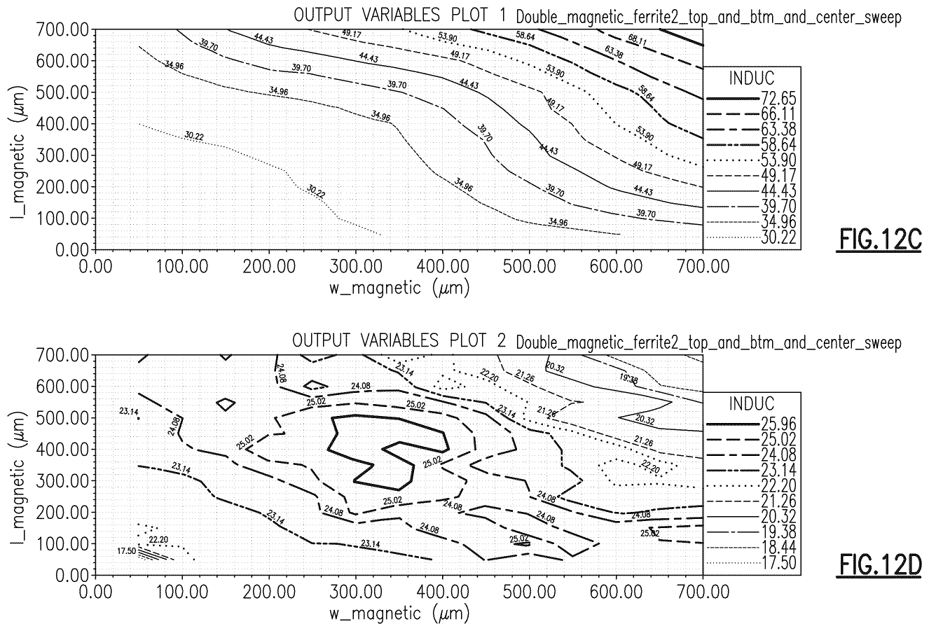

FIG. 12A is a graph showing inductance of an integrated inductor of Type H described with respect to FIG. 7B for different engineered material structure dimensions using cobalt iron hafnium oxide (CoFeHfO) as the engineered material structure 18. FIG. 12B is a graph showing the quality factor of the integrated inductor of Type H used in FIG. 12A. FIG. 12C is a graph showing inductance of an integrated inductor of Type H described with respect to FIG. 7B for different engineered material structure dimensions using cobalt zirconium tantalum (CoZrTa) as the engineered material structure 18. FIG. 12D is a graph showing the quality factor of the integrated inductor of Type H used in FIG. 12C.

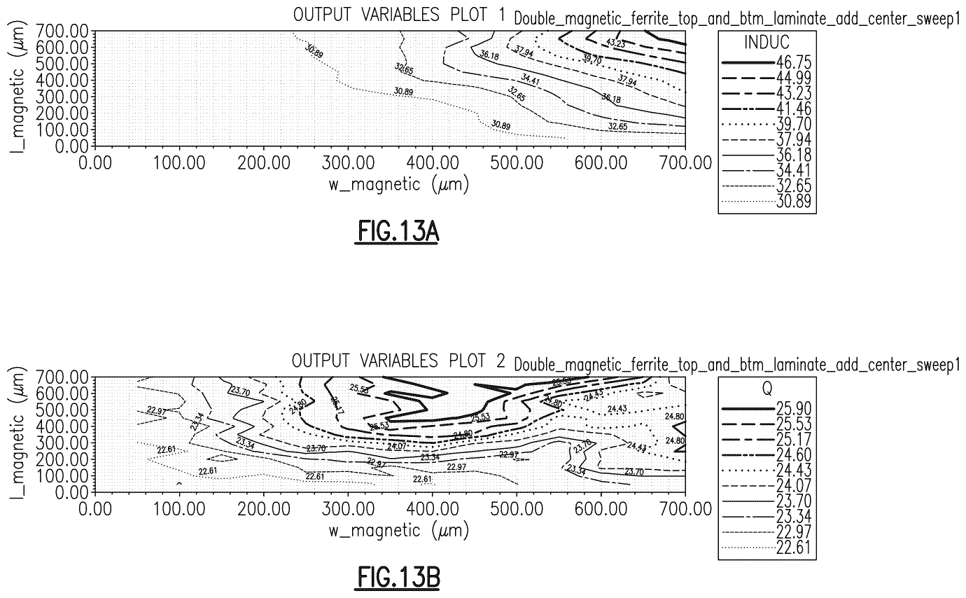

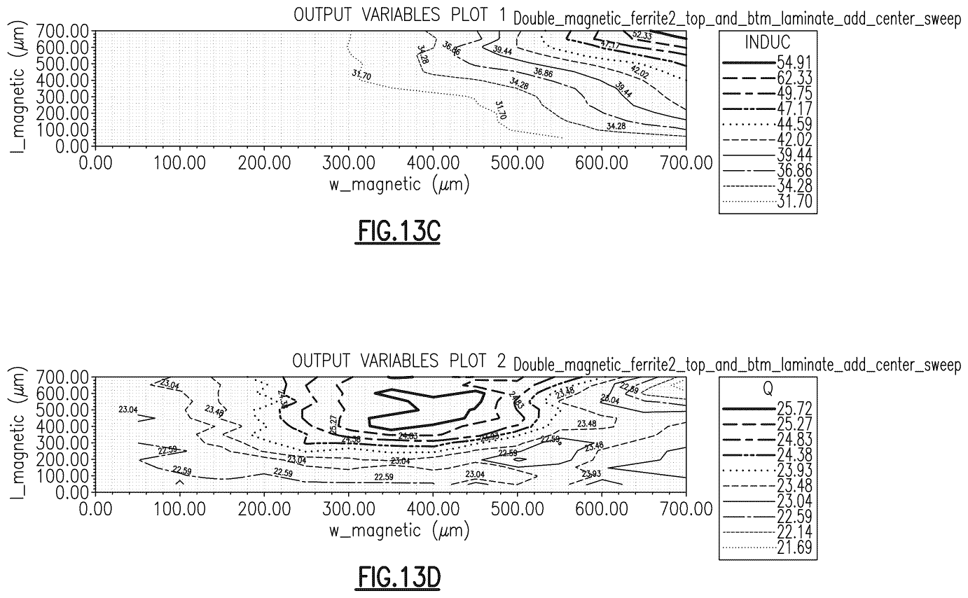

FIG. 13A is a graph showing inductance of an integrated inductor of Type I described with respect to FIG. 7B for different engineered material structure dimensions using cobalt iron hafnium oxide (CoFeHfO) as the engineered material structure 18. FIG. 13B is a graph showing the quality factor of the integrated inductor of Type I used in FIG. 13A. FIG. 13C is a graph showing inductance of an integrated inductor of Type I described with respect to FIG. 7B for different engineered material structure dimensions using cobalt zirconium tantalum (CoZrTa) as the engineered material structure 18. FIG. 13D is a graph showing the quality factor of the integrated inductor of Type I used in FIG. 13C.

The simulation results of FIGS. 8A-13D can be used to determine the dimensions of the engineered material structure 18 to provide desired inductor performance. Dimensions and materials of other components in an integrated inductor may be selected to further improve inductor performance. For example, the thickness and/or the material of a meatal layer that forms the spiral coil can affect the inductance and/or the Q.

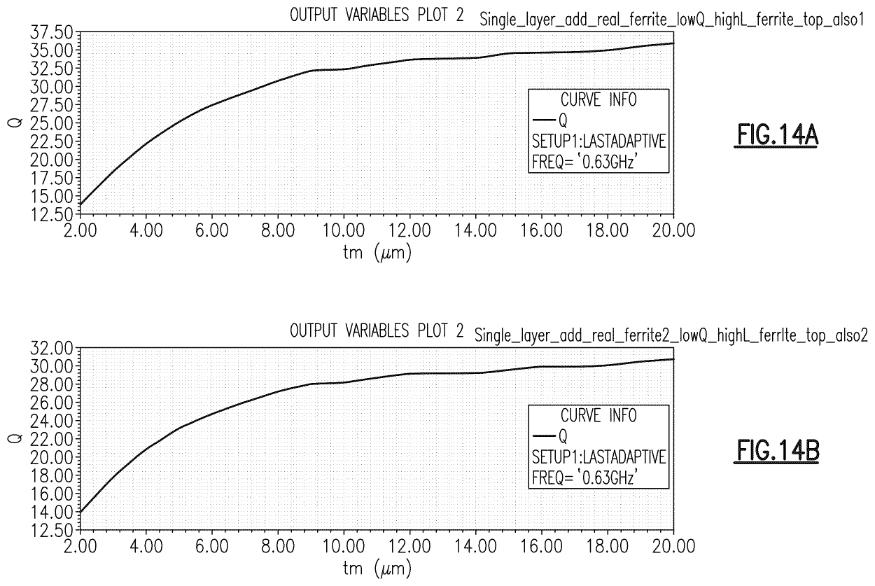

FIG. 14A is a graph showing the quality factor of an integrated inductor of Type B described with respect to FIG. 7A for different metal thicknesses of the single layer spiral coil structure 32 when cobalt iron hafnium oxide (CoFeHfO) is used as the engineered material structure 18. FIG. 14B is a graph showing the quality factor of an integrated inductor of Type B described with respect to FIG. 7A for different metal thicknesses of the single layer spiral coil structure 32 when cobalt zirconium tantalum (CoZrTa) is used as the engineered material structure 18. FIGS. 14A and 14B can indicate that the quality factor can be improved significantly as the thickness increases from 2 μm to about 12 μm, and the quality factor remains generally at the same level after about 12 μm.

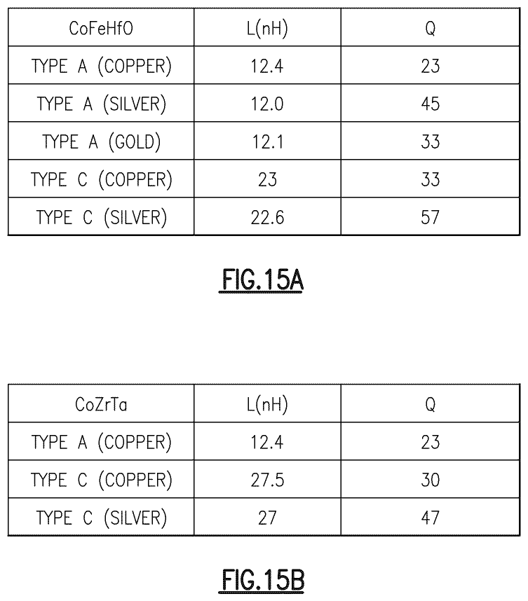

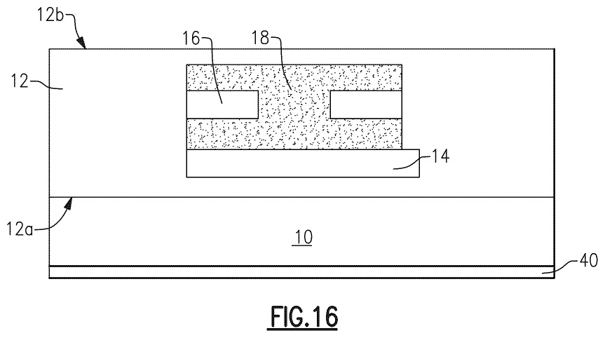

FIG. 15A is a chart showing the inductance L in nano henry (nH) and the quality factor of integrated inductors of Type A and Type C described with respect to FIG. 7A for different metals of the single layer spiral coil structure 32 when cobalt iron hafnium oxide (CoFeHfO) is used as the engineered material structure 18. FIG. 15B is a chart showing the inductance L in nano henry (nH) and the quality factor of integrated inductors of Type A and Type C described with respect to FIG. 7A for different metals of the single layer spiral coil structure 32 when cobalt zirconium tantalum (CoZrTa) is used as the engineered material structure 18. FIGS. 15A and 15B can indicate that silver and gold can improve the quality factor as compared to copper when used as the coil structure 32 without significantly affecting the inductance.

In some embodiments, a ground (GND) layer can be provided with an integrated inductor to provide a ground connection. The ground connection can make the integrated inductor more reliable.

FIG. 16 is a schematic cross-sectional side view of a stack of layers that can be implemented in one or more of the integrated inductors disclosed herein. Unless otherwise noted, the components shown in FIG. 16 may be structurally and/or functionally the same as or generally similar to like components disclosed herein. The structure shown in FIG. 16 can be generally similar to the structure of FIG. 5B, except that in FIG. 16, a ground layer 40 is included. The ground layer 40 can include any suitable material. For example, the ground layer 40 can include metals such as copper, silver, or gold. A distance between the ground layer 40 and a metal layer that forms a spiral coil of an integrated inductor can affect the inductance and the quality factor of the integrated inductor.

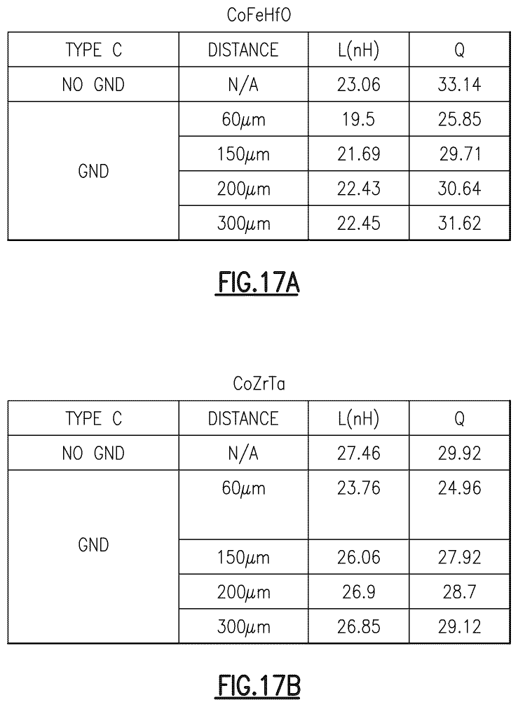

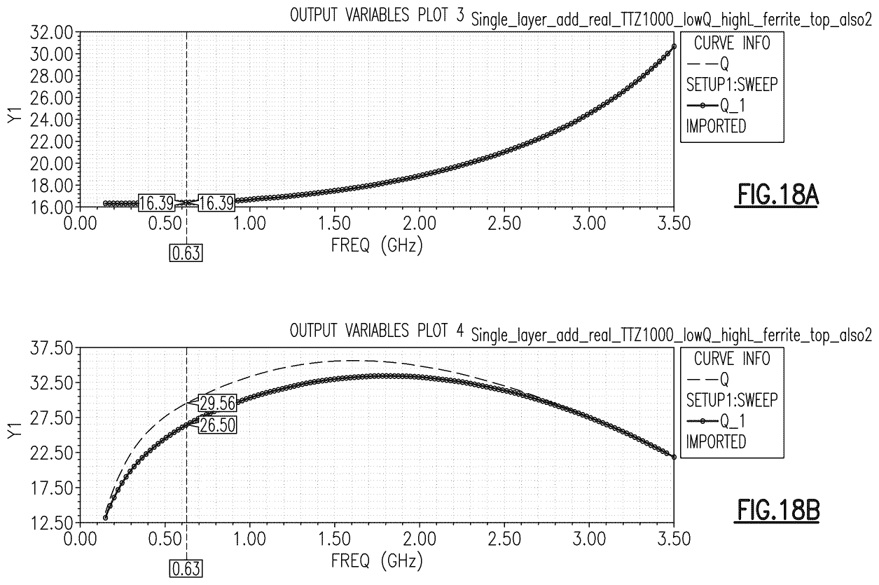

FIG. 17A is a chart showing the inductance L in nano henry (nH) and the quality factor of integrated inductors of Type C described with respect to FIG. 7A with the ground layer 40 shown in FIG. 16 for different distances between the single layer spiral coil structure 32 and the ground layer 40 when cobalt iron hafnium oxide (CoFeHfO) is used as the engineered material structure 18. FIG. 17B is a chart showing the inductance L in nano henry (nH) and the quality factor of integrated inductors of Type C described with respect to FIG. 7A with the ground layer 40 shown in FIG. 16 for different distances between the single layer spiral coil structure 32 and the ground layer 40 when cobalt zirconium tantalum (CoZrTa) is used as the engineered material structure 18.

FIGS. 17A and 17B indicate that when the ground layer is relatively close to the spiral coil structure 32, the inductance and the quality factor may be degraded. In some embodiments, it can be preferred to have a separation distance between the spiral coil structure 32 and the ground layer 40 of at least 150 μm, at least 200 μm, at least 250 μm, or at least 300 μm.

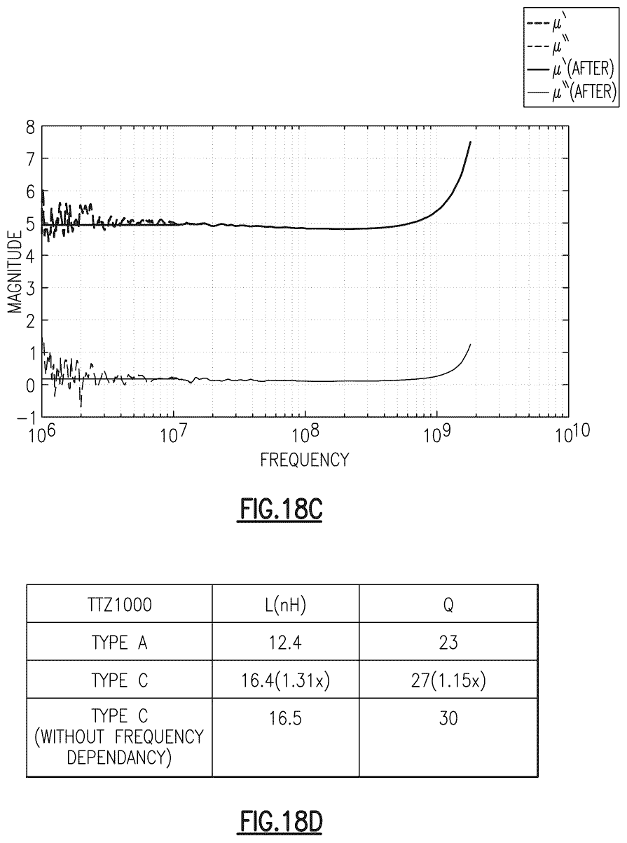

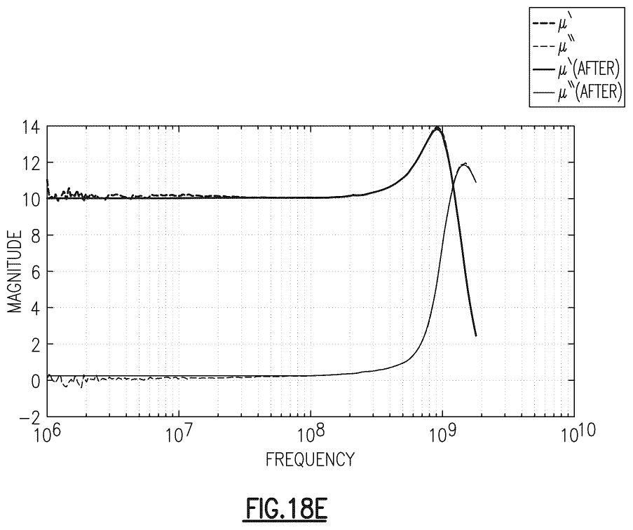

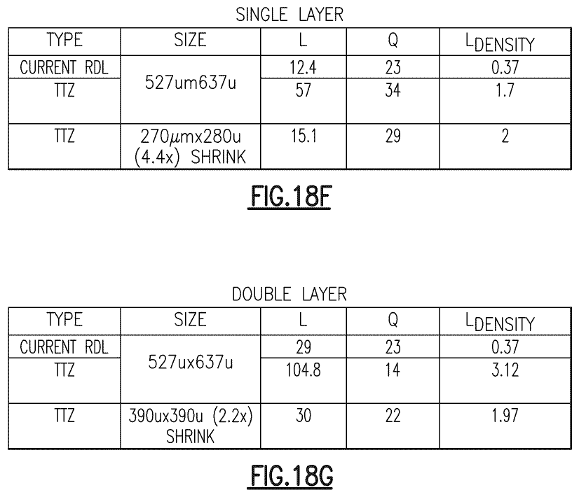

FIG. 18A is a graph showing inductance as a function of frequency for an inductor having a structure similar to FIG. 5C including TTZ1000 as the material of the engineered material structure 18. FIG. 18B is a graph showing quality factor of the inductor of FIG. 18A as a function of frequency for two cases, one when the permeability is constant for TTZ1000 and one where the permeability is a function of frequency as shown in FIGS. 18C and 18E. FIG. 18C is a graph showing example permeability of TTZ1000 as a function of frequency. FIG. 18D is a chart showing the inductance and the quality factor of integrated inductors of Type A and Type C when TTZ1000 is used as the material of the engineered material structure 18. The inductance and Q for Type A (when no ferromagnet is used), and Type C (when ferromagnet is used for engineered material and when ferromagnet is used and its permeability is a function of frequency). FIG. 18E is a graph showing permeability of TTZ1000 as a function of frequency. FIGS. 18F and 18G are charts showing inductance, quality factor, and inductance density simulation results of different inductors. In the inductors used for the simulations of FIG. 18F, a single layer spiral of FIG. 6A is implemented and in the inductors used for the simulations of FIG. 18G, a double layer spiral of FIG. 6B is used. The inductors with TTZ1000 have a cross-section similar to FIG. 5C.

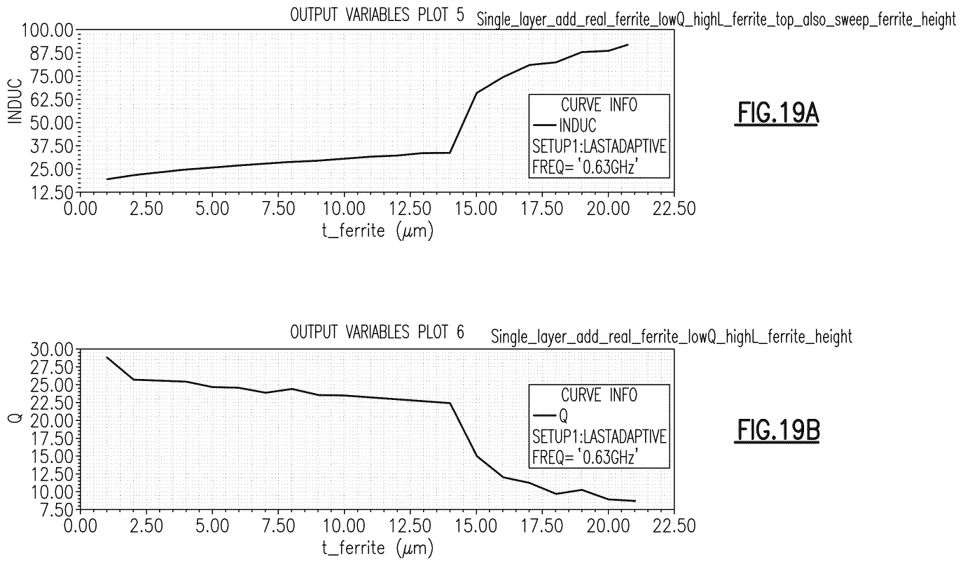

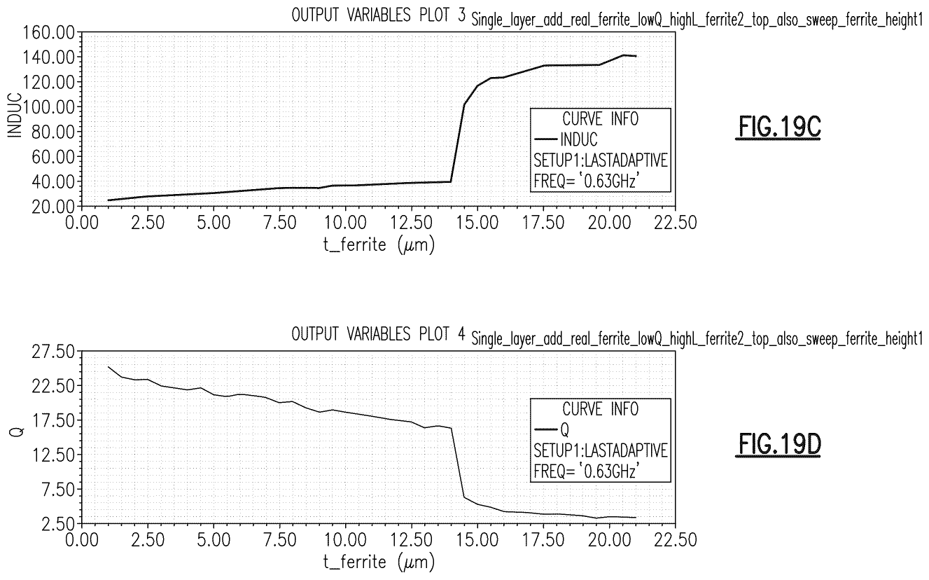

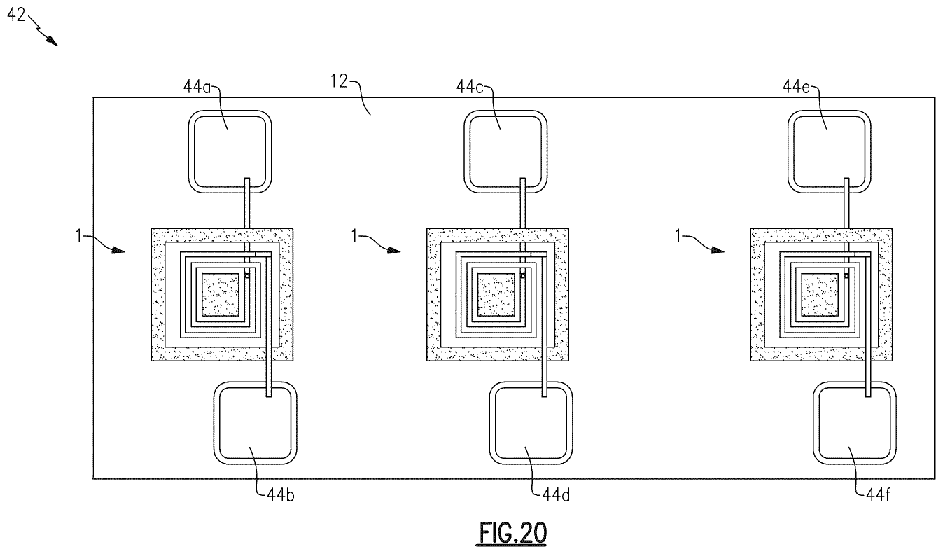

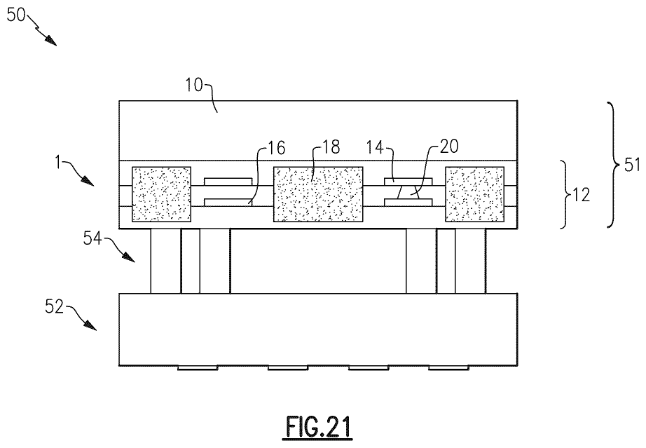

FIGS. 19A and 19B are graphs showing inductance and the quality factor (Q), respectively, as a function of thickness of the engineered material structure 18 in an integrated inductor of Type H described with respect to FIG. 7A when cobalt iron hafnium oxide (CoFeHfO) is used as the engineered material structure 18. FIGS. 19C and 19D are graphs showing inductance and the Q as a function of thickness of the engineered material structure 18 in an integrated inductor of Type H described with respect to FIG. 7A when cobalt zirconium tantalum (CoZrTa) is used as the engineered material structure 18. FIGS. 19A to 19D indicate that the quality factor can significantly degrade when the thickness of the engineered material structure 18 is such that the engineered material structure 18 makes contact with the first metal layer 14.

In some embodiments, two or more integrated inductors disclosed herein can be included in a single die or next to each other in a die or on the PCB. For example, two or more identical integrated inductors can be included in the single die. For another example, two or more different integrated inductors can be included in the single die.

FIG. 20 is a schematic top plan view of an inductor die 42 according to an embodiment. The inductor die 42 can include three integrated inductors 1 provided on a common substrate. Unless otherwise noted, the components shown in FIG. 20 may be structurally and/or functionally the same as or generally similar to like components disclosed herein. The inductor die 42 can include two terminals 44a and 44b, 44c and 44d, 44c and 44f for each of the three integrated inductors 1. The terminals 44a-44f can be electrically coupled to, for example, terminals of a larger system, a packaging substrate, or an external device.

FIG. 21 is a schematic cross-sectional side view of a packaged acoustic wave device 50 according to an embodiment. Unless otherwise noted, the components shown in FIG. 21 may be structurally and/or functionally the same as or generally similar to like components disclosed herein. The packaged acoustic wave device 50 can include a cap structure 51 that includes one or more of the integrated inductors 1 disclosed herein. An acoustic wave device 52 is coupled to the integrated inductor 1 by way of a connecting structure 54.

The acoustic wave device 52 can include an acoustic wave filter. An acoustic wave filter can include a plurality of acoustic wave resonators arranged to filter a radio frequency signal. Example acoustic wave resonators include surface acoustic wave (SAW) resonators and bulk acoustic wave (BAW) resonators. Example SAW resonators can include temperature compensated surface acoustic wave (TC-SAW) resonators and multi-layer piezoelectric substrate surface acoustic wave (MPS-SAW) resonators. Example BAW resonators include film bulk acoustic wave resonators (FBARs) and BAW solidly mounted resonators (SMRs).

The connecting structure 54 can include one or more pillars. The one or more pillars may include a conductive pillar that can provide electrical communication between the integrated inductor 1 and the acoustic wave device 52. The connecting structure 54 may include a seal ring.

Including an integrated inductor in the cap structure can reduce performance losses (e.g., resistive losses, dielectric losses, or leakage losses and space losses) and the space loss, as compared to providing the integrated inductor separate from the packaged acoustic wave device 50.

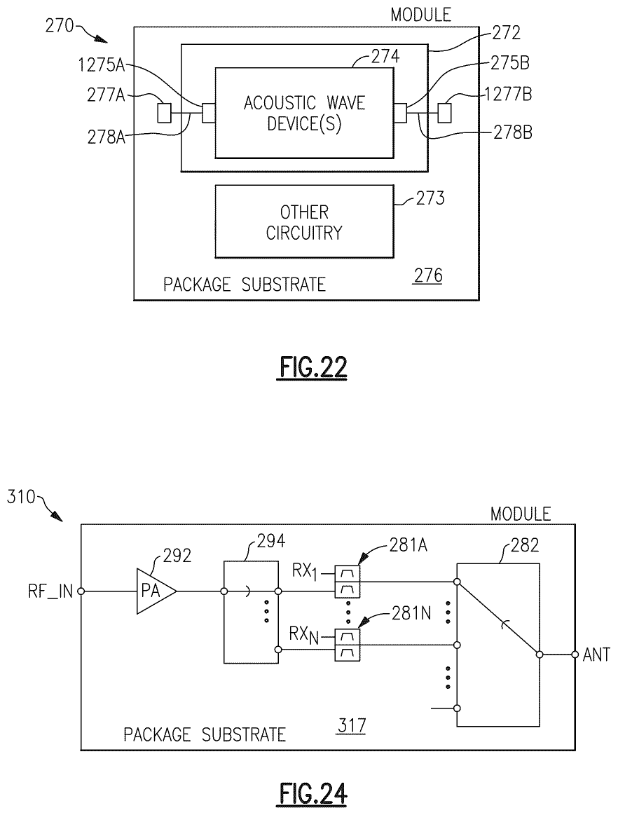

Integrated inductors disclosed herein can be implemented in a variety of packaged modules. Some example packaged modules will now be disclosed in which any suitable principles and advantages of the integrated inductors disclosed herein can be implemented. The example packaged modules can include a package that encloses the illustrated circuit elements. A module that includes a radio frequency component can be referred to as a radio frequency module. The illustrated circuit elements can be disposed on a common packaging substrate. The packaging substrate can be a laminate substrate, for example. FIGS. 22, 23, and 24 are schematic block diagrams of illustrative packaged modules according to certain embodiments. Any suitable combination of features of these packaged modules can be implemented with each other. The integrated inductor or a component that includes one or more integrated inductors in accordance with various embodiments disclosed herein may be embedded in or be part of a packaging substrate or may be mounted as a component on the packaging substrate.

FIG. 22 is a schematic diagram of a radio frequency module 270 that includes an acoustic wave component 272. The illustrated radio frequency module 270 includes the acoustic wave component 272 and other circuitry 273. The acoustic wave component 272 can include an acoustic wave filter that includes a plurality of acoustic wave devices, for example. The acoustic wave devices can be BAW devices in certain applications. One or more integrated inductors in accordance with various embodiments can be implemented in any suitable locations of the radio frequency module 270. For example, the other circuitry 273 may include one or more integrated inductors.

The acoustic wave component 272 shown in FIG. 22 includes one or more acoustic wave devices 274 and terminals 275A and 275B. The one or more acoustic wave devices 274 include one or more BAW devices or SAW devices. The terminals 275A and 274B can serve, for example, as an input contact and an output contact. Although two terminals are illustrated, any suitable number of terminals can be implemented for a particular application. The acoustic wave component 272 and the other circuitry 273 are on a common packaging substrate 276 in FIG. 22. The packaging substrate 276 can be a laminate substrate. The terminals 275A and 275B can be electrically connected to contacts 277A and 277B, respectively, on the packaging substrate 276 by way of electrical connectors 278A and 278B, respectively. The electrical connectors 278A and 278B can be bumps or wire bonds, for example.

The other circuitry 273 can include any suitable additional circuitry. For example, the other circuitry can include one or more radio frequency amplifiers (e.g., one or more power amplifiers and/or one or more low noise amplifiers), one or more radio frequency switches, one or more additional filters, one or more RF couplers, one or more delay lines, one or more phase shifters, the like, or any suitable combination thereof. Accordingly, the other circuitry 273 can include one or more radio frequency circuit elements. The other circuitry 273 can be electrically connected to the one or more acoustic wave devices 274. The radio frequency module 270 can include one or more packaging structures to, for example, provide protection and/or facilitate easier handling of the radio frequency module 270. Such a packaging structure can include an overmold structure formed over the packaging substrate 276. The overmold structure can encapsulate some or all of the components of the radio frequency module 270.

FIG. 23 is a schematic block diagram of a module 300 that includes filters 302A to 302N, a radio frequency switch 304, and a low noise amplifier 306. In some embodiments, one or more integrated inductors according to various embodiments disclosed herein can be used for impedance matching of the filters 302A to 302N and a low noise amplifier 306. Any suitable number of filters 302A to 302N can be implemented. The illustrated filters 302A to 302N are receive filters. One or more of the filters 302A to 302N can be included in a multiplexer that also includes a transmit filter and/or another receive filter. The radio frequency switch 304 can be a multi-throw radio frequency switch. The radio frequency switch 304 can electrically couple an output of a selected filter of filters 302A to 302N to the low noise amplifier 306. In some embodiments, a plurality of low noise amplifiers can be implemented. The module 300 can include diversity receive features in certain applications.

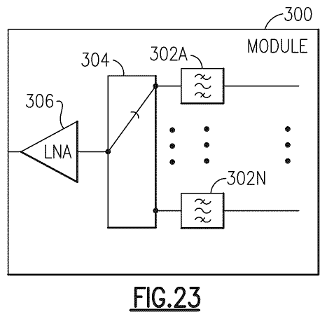

FIG. 24 is a schematic diagram of a radio frequency module 310 that can include one or more integrated inductors according to various embodiments disclosed herein, according to an embodiment. As illustrated, the radio frequency module 310 includes duplexers 316A to 316N, a power amplifier 312, a radio frequency switch 314 configured as a select switch, and an antenna switch 318. The radio frequency module 310 can include a package that encloses the illustrated elements. The illustrated elements can be disposed on a common packaging substrate 317. The packaging substrate 317 can be a laminate substrate, for example. A radio frequency module that includes a power amplifier can be referred to as a power amplifier module. A radio frequency module can include a subset of the elements illustrated in FIG. 24 and/or additional elements.

The duplexers 316A to 316N can each include two acoustic wave filters coupled to a common node. For example, the two acoustic wave filters can be a transmit filter and a receive filter. As illustrated, the transmit filter and the receive filter can each be a band pass filter arranged to filter a radio frequency signal. One or more of the transmit filters can include a BAW device in accordance with any suitable principles and advantages disclosed herein. Similarly, one or more of the receive filters can include a BAW device in accordance with any suitable principles and advantages disclosed herein. Although FIG. 24 illustrates duplexers, any suitable principles and advantages disclosed herein can be implemented in other multiplexers (e.g., quadplexers, hexaplexers, octoplexers, etc.) and/or in switched multiplexers and/or with standalone filters.

The power amplifier 312 can amplify a radio frequency signal. The illustrated radio frequency switch 314 is a multi-throw radio frequency switch. The radio frequency switch 314 can electrically couple an output of the power amplifier 312 to a selected transmit filter of the transmit filters of the duplexers 316A to 316N. In some instances, the radio frequency switch 314 can electrically connect the output of the power amplifier 312 to more than one of the transmit filters. The antenna switch 318 can selectively couple a signal from one or more of the duplexers 316A to 316N to an antenna port ANT. The duplexers 316A to 316N can be associated with different frequency bands and/or different modes of operation (e.g., different power modes, different signaling modes, etc.).

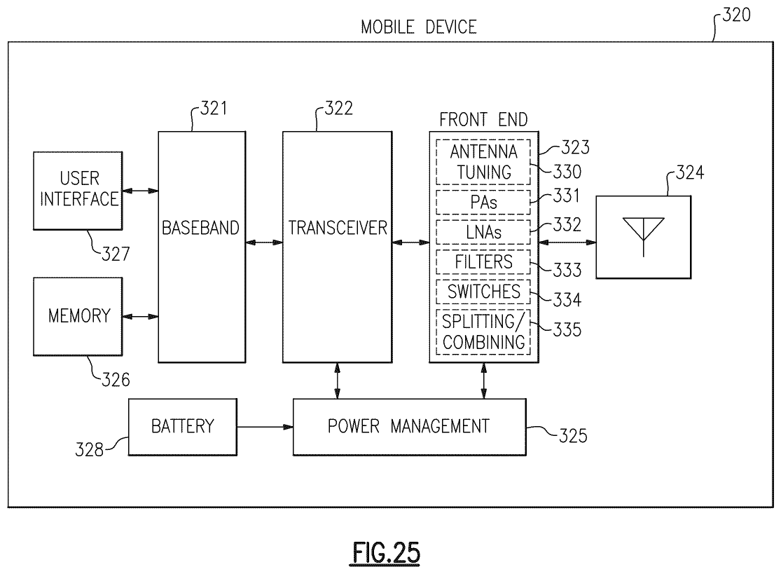

FIG. 25 is a schematic block diagram of a wireless communication device 320 that includes an integrated inductor according to an embodiment. The wireless communication device 320 can be a mobile device. The wireless communication device 320 can be any suitable wireless communication device. For instance, a wireless communication device 320 can be a mobile phone, such as a smart phone. As illustrated, the wireless communication device 320 includes a baseband system 321, a transceiver 322, a front end system 323, one or more antennas 324, a power management system 325, a memory 326, a user interface 327, and a battery 328.

The wireless communication device 320 can be used communicate using a wide variety of communications technologies, including, but not limited to, 2G, 3G, 4G (including LTE, LTE-Advanced, and/or LTE-Advanced Pro), 5G NR, WLAN (for instance, Wi-Fi), WPAN (for instance, Bluetooth and/or ZigBee), WMAN (for instance, WiMax), and/or GPS technologies.

The transceiver 322 generates RF signals for transmission and processes incoming RF signals received from the antennas 324. Various functionalities associated with the transmission and receiving of RF signals can be achieved by one or more components that are collectively represented in FIG. 25 as the transceiver 322. In one example, separate components (for instance, separate circuits or dies) can be provided for handling certain types of RF signals.

The front end system 323 aids in conditioning signals provided to and/or received from the antennas 324. In the illustrated embodiment, the front end system 323 includes antenna tuning circuitry 330, power amplifiers (PAS) 331, low noise amplifiers (LNAs) 332, filters 333, switches 334, and signal splitting/combining circuitry 335. However, other implementations are possible. Integrate inductors in accordance with any suitable principles and advantages disclosed herein can be provided for impedance matching between two or more components of the wireless communication device.

For example, the front end system 323 can provide a number of functionalities, including, but not limited to, amplifying signals for transmission, amplifying received signals, filtering signals, switching between different bands, switching between different power modes, switching between transmission and receiving modes, duplexing of signals, multiplexing of signals, or any suitable combination thereof.

In certain implementations, the wireless communication device 320 supports carrier aggregation, thereby providing flexibility to increase peak data rates. Carrier aggregation can be used for Frequency Division Duplexing (FDD) and/or Time Division Duplexing (TDD), and may be used to aggregate a plurality of carriers and/or channels. Carrier aggregation includes contiguous aggregation, in which contiguous carriers within the same operating frequency band are aggregated. Carrier aggregation can also be non-contiguous, and can include carriers separated in frequency within a common band or in different bands.

The antennas 324 can include antennas used for a wide variety of types of communications. For example, the antennas 324 can include antennas for transmitting and/or receiving signals associated with a wide variety of frequencies and communications standards.

In certain implementations, the antennas 324 support MIMO communications and/or switched diversity communications. For example, MIMO communications use multiple antennas for communicating multiple data streams over a single radio frequency channel. MIMO communications benefit from higher signal to noise ratio, improved coding, and/or reduced signal interference due to spatial multiplexing differences of the radio environment. Switched diversity refers to communications in which a particular antenna is selected for operation at a particular time. For example, a switch can be used to select a particular antenna from a group of antennas based on a variety of factors, such as an observed bit error rate and/or a signal strength indicator.

The wireless communication device 320 can operate with beamforming in certain implementations. For example, the front end system 323 can include amplifiers having controllable gain and phase shifters having controllable phase to provide beam formation and directivity for transmission and/or reception of signals using the antennas 324. For example, in the context of signal transmission, the amplitude and phases of the transmit signals provided to the antennas 324 are controlled such that radiated signals from the antennas 324 combine using constructive and destructive interference to generate an aggregate transmit signal exhibiting beam-like qualities with more signal strength propagating in a given direction. In the context of signal reception, the amplitude and phases are controlled such that more signal energy is received when the signal is arriving to the antennas 324 from a particular direction. In certain implementations, the antennas 324 include one or more arrays of antenna elements to enhance beamforming.

The baseband system 321 is coupled to the user interface 327 to facilitate processing of various user input and output (I/O), such as voice and data. The baseband system 321 provides the transceiver 322 with digital representations of transmit signals, which the transceiver 322 processes to generate RF signals for transmission. The baseband system 321 also processes digital representations of received signals provided by the transceiver 322. As shown in FIG. 25, the baseband system 321 is coupled to the memory 326 of facilitate operation of the wireless communication device 320.

The memory 326 can be used for a wide variety of purposes, such as storing data and/or instructions to facilitate the operation of the wireless communication device 220 and/or to provide storage of user information.

The power management system 325 provides a number of power management functions of the wireless communication device 320. In certain implementations, the power management system 325 includes a PA supply control circuit that controls the supply voltages of the power amplifiers 331. For example, the power management system 325 can be configured to change the supply voltage(s) provided to one or more of the power amplifiers 331 to improve efficiency, such as power added efficiency (PAE).

As shown in FIG. 25, the power management system 325 receives a battery voltage from the battery 328. The battery 328 can be any suitable battery for use in the wireless communication device 320, including, for example, a lithium-ion battery.

Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes example embodiments, the teachings described herein can be applied to a variety of structures. Any of the principles and advantages discussed herein can be implemented in association with RF circuits configured to process signals having a frequency in a range from about 30 kHz to 300 GHz, such as in a frequency range from about 400 MHz to 8.5 GHz, in FR1, in a frequency range from about 2 GHz to 10 GHz, in a frequency range from about 2 GHz to 15 GHz, or in a frequency range from 5 GHz to 20 GHz.

Aspects of this disclosure can be implemented in various electronic devices. Examples of the electronic devices can include, but are not limited to, consumer electronic products, parts of the consumer electronic products such as packaged radio frequency modules, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a robot such as an industrial robot, an Internet of things device, a stereo system, a digital music player, a radio, a camera such as a digital camera, a portable memory chip, a home appliance such as a washer or a dryer, a peripheral device, a wrist watch, a clock, etc. Further, the electronic devices can include unfinished products.

Unless the context indicates otherwise, throughout the description and the claims, the words “comprise,” “comprising,” “include,” “including” and the like are to generally be construed in an inclusive sense, as opposed to an exclusive or exhaustive sense; that is to say, in the sense of “including, but not limited to.” Conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively.

While certain embodiments have been described, these embodiments have been presented by way of example only, and are not intended to limit the scope of the disclosure. Indeed, the novel resonators, filters, multiplexer, devices, modules, wireless communication devices, apparatus, methods, and systems described herein may be embodied in a variety of other forms. Furthermore, various omissions, substitutions, and changes in the form of the resonators, filters, multiplexer, devices, modules, wireless communication devices, apparatus, methods, and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and/or acts of the various embodiments described above can be combined to provide further embodiments. The accompanying claims and their equivalents are intended to cover such forms or modifications as would fall within the scope and spirit of the disclosure.

What is claimed is:

1. An integrated inductor comprising:
a support substrate;
a dielectric structure having a first side facing the support substrate and a second side opposite the first side;
a spiral coil structure between the first side and the second side of the dielectric structure; and
a ferromagnetic material structure at least partially between the support substrate and the second side.

2. The integrated inductor of claim 1 wherein the ferromagnetic material structure includes a material that has a relative permeability is in a range between 100 and 1000.

3. The integrated inductor of claim 2 wherein the ferromagnetic material structure has a resistivity in a range between 75 (2 cm and 2000 Ωcm.

4. The integrated inductor of claim 1 wherein the ferromagnetic material structure includes cobalt iron hafnium oxide (CoFeHfO).

5. The integrated inductor of claim 1 wherein the ferromagnetic material structure includes cobalt zirconium tantalum (CoZrTa).

6. The integrated inductor of claim 1 wherein a thickness of the dielectric structure between the first side and the second side is in a range between 45 μm and 150 μm.

7. The integrated inductor of claim 1 wherein the spiral coil structure includes a first coil defined by a first metal layer and a second coil defined by a second metal layer.

8. The integrated inductor of claim 1 is a wafer-level integrated inductor.

9. The integrated inductor of claim 1 wherein the ferromagnetic material structure is patterned to reduce losses due to eddy current.

10. The integrated inductor of claim 1 wherein the ferromagnetic material structure includes slits.

11. The integrated inductor of claim 1 having a core region and a peripheral region, wherein the ferromagnetic material structure includes a core portion positioned in the core region and a peripheral portion positioned in the peripheral region.

12. The integrated inductor of claim 1 wherein at least a portion of the ferromagnetic material structure is positioned laterally between two portions of the spiral coil structure.

13. The integrated inductor of claim 1 wherein at least a portion of the ferromagnetic material structure is positioned between the spiral coil structure and the second side of the dielectric structure.

14. The integrated inductor of claim 1 wherein the ferromagnetic material structure surrounds the spiral coil structure.

15. The integrated inductor of claim 1 further includes a ground layer.

16. The integrated inductor of claim 1 further comprising one or more additional integrated inductors on the support substrate.

17. The integrated inductor of claim 1 further comprising:
a cap structure that includes the integrated inductor; and
an acoustic wave device coupled to the integrated inductor by way of a connecting structure.

18. The integrated inductor of claim 17 wherein the acoustic wave device includes an acoustic wave filter.

19. An integrated inductor having a core region and a peripheral region, the integrated inductor comprising:
a support substrate;
a dielectric layer having a first side facing the support substrate and a second side opposite the first side;
a spiral coil between the first side and the second side of the dielectric layer; and
a ferromagnetic material structure at least in the core region.

20. An integrated inductor comprising:
a support substrate;
a dielectric layer having a first side facing the support substrate and a second side opposite the first side;
a spiral coil between the first side and the second side of the dielectric layer; and
a ferromagnetic material structure positioned within a magnetic field generated by the spiral coil.
